(19) United States
(12) Patent Application Publication
(10) Pub. No.: US 2022/0137228 A1
(43) Pub. Date: May 5, 2022

(54) MIRROR ASSEMBLY HAVING REINFORCEMENT STRUCTURE FOR LIGHT STEERING

(71) Applicant: Beijing Voyager Technology Co., Ltd., Beijing (CN)

(72) Inventors: Youmin Wang, Mountain View, CA (US); Yufeng Wang, Mountain View, CA (US); Gary Li, Mountain View, CA (US)

(21) Appl. No.: 17/090,667

(22) Filed: Nov. 5, 2020

(51) Int. Cl. G01S 17/931; G02B 26/08; B81B 3/00; G01S 7/484; G01S 7/486

(52) U.S. Cl. CPC G01S 17/931; G02B 26/0833; B81B 2201/042; G01S 7/484; G01S 7/486; B81B 3/0083

(57) ABSTRACT

In one example, an apparatus is provided. The apparatus is part of a Light Detection and Ranging (LiDAR) module of a vehicle and comprising: a semiconductor integrated circuit comprising a microelectromechanical system (MEMS) and a substrate, the MEMS comprising an array of micro-mirror assemblies. Each micro-mirror assembly comprises: a micro-mirror having a pixelated pattern of reinforcement structures on a back-side surface, the pixelated pattern being defined based on dividing the back-side surface into an array of pixels and comprising protrusion structures that protrude from the back-side surface, the pixelated pattern of reinforcement structures comprising non-uniform sub-patterns having non-uniform geometric planar shapes, non-uniform planar sizes, and non-uniform planar orientations on the back-side surface; and an actuator to rotate the micro-mirror to reflect light emitted by a light source out of the LiDAR module or to reflect light received by the LiDAR module to a receiver.

Light steering typically involves the projection of light in a predetermined direction to facilitate, for example, the detection and ranging of an object, the illumination and scanning of an object, or the like. Light steering can be used in many different fields of applications, including, for example, autonomous vehicles or medical diagnostic devices.

Light steering can be performed in both transmission and reception of light. For example, a light steering transmitter may include a micro-mirror array to control the projection direction of light to detect/image an object. Moreover, a light steering receiver may also include a micro-mirror array to select a direction of incident light to be detected by the receiver, to avoid detecting other unwanted signals. The micro-mirror array may include an array of micro-mirror assemblies, with each micro-mirror assembly comprising a micro-mirror and an actuator. In a micro-mirror assembly, a micro-mirror can be mechanically connected to a substrate. As used herein, “mechanically connected” or “connected” can include a direct connection or an indirect connection. For example, the micro-mirror can be indirectly connected to the substrate via a connection structure (e.g., a torsion bar, a spring) to form a pivot point.

A micro-mirror can be rotated around the pivot point by an actuator. Each micro-mirror can be rotated by a rotation angle to reflect (and steer) light towards a target direction. It is desirable that the micro-mirror maintains a flat light-reflecting surface as the micro-mirror rotates to reduce the dispersion of the reflected light, which can negatively impact the performance of the light steering operation.

### BRIEF SUMMARY

In one example, an apparatus is provided. The apparatus is part of a Light Detection and Ranging (LiDAR) module of a vehicle and comprises: a semiconductor integrated circuit comprising a microelectromechanical system (MEMS) and a substrate, the MEMS comprising an array of micro-mirror assemblies, each micro-mirror assembly comprising: a micro-mirror having a pixelated pattern of reinforcement structures on a back-side surface, the pixelated pattern being defined based on dividing the back-side surface into an array of pixels and comprising protrusion structures that protrude from the back-side surface, the pixelated pattern of reinforcement structures comprising non-uniform sub-patterns having non-uniform geometric planar shapes, non-uniform planar sizes, and non-uniform planar orientations on the back-side surface; and an actuator to rotate the micro-mirror to reflect light emitted by a light source out of the LiDAR module or to reflect light received by the LiDAR module to a receiver.

In some aspects, the pixelated pattern of reinforcement structures comprises a first reinforcement structure and a second reinforcement structure, the first reinforcement structure forming a pixelated slanted line with respect to the second reinforcement structure.

In some aspects, the pixelated pattern of reinforcement structures comprises a first reinforcement structure and a second reinforcement structure, the first reinforcement structure and the second reinforcement structure having no connecting reinforcement structure in between.

In some aspects, the pixelated pattern of reinforcement structures comprises at least one of: a first reinforcement structure having a non-uniform width that spans a non-uniform number of pixels; or second reinforcement structures that are parallel with each other and having different lengths that span different numbers of pixels.

In some aspects, the pixelated pattern of reinforcement structures comprises a plurality of identical pixelated sub-patterns.

In some aspects, the pixelated pattern of reinforcement structures is determined based on reducing or minimizing a degree of deformation of the micro-mirror across a range of rotation angles of the micro-mirror.

In some aspects, the pixelated pattern of reinforcement structures is determined based on increasing or maximizing a power efficiency of the micro-mirror across a range of rotation angles of the micro-mirror. The power efficiency defines a ratio of power between first light received in a predetermined window in a far field from the micro-mirror with deformation and second light received in the predetermined window in the far field from the micro-mirror without deformation.

In some aspects, the pixelated pattern of reinforcement structures is determined based on an optimization operation that trades off between a power efficiency of the micro-mirror and an attribute of the pixelated pattern. The power efficiency defines a ratio of power between first light received in a predetermined window in a far field from the micro-mirror with deformation and second light received in the predetermined window in the far field from the micro-mirror without deformation.

In some aspects, the attribute includes a total number of pixels of the pixelated pattern having a reinforcement structure.

In some aspects, the attribute includes a moment of inertia of micro-mirror having the pixelated pattern of reinforcement structures.

In some aspects, the optimization operation includes at least one of: a particle swarm optimization (PSO) operation, a gradient descent operation, a quasi-newton method, or a newton method.

In some aspects, the optimization operation generates a raw pixelated pattern. The pixelated pattern of reinforcement structures is fabricated based on a mask pattern. The mask pattern is generated by expanding pixels of the raw pixelated pattern to compensate for etching undercut.

In some aspects, the apparatus further comprises a gimbal structure surrounding and coupled with the micro-mirror. The actuator is coupled with the gimbal structure and is configured to rotate the micro-mirror based on rotating the gimbal structure.

In some aspects, the apparatus further comprises a controller. The light source is a pulsed light source. The controller is configured to: control the light source to generate a first light pulse at a first time; control the actuator to set a first angle of an output projection path to project the first light pulse towards an object along the output projection path; control the actuator to set a second angle of an input path to steer a second light pulse reflected from the object to the receiver, the second light pulse being received at the receiver at a second time; and determine a location of the object with respect to the apparatus based on a difference between the first time and the second time, the first angle, and the second angle.

In one example, a computer-implemented method of generating a mask pattern for fabricating a micro-mirror is provided. The method comprises: obtaining a candidate pixelated pattern of reinforcement structures to be formed on a back side of the micro-mirror; determining one or more first attributes of the micro-mirror having the candidate pixelated pattern, the one or more first attributes comprising at least one of: a total moment of inertia of the micro-mirror or a total number of pixels of the pixelated pattern having a protrusion structure; determining one or more second attributes of the micro-mirror having the candidate pixelated pattern, the one or more second attributes comprising at least one of: a degree of deformation of the micro-mirror across a range of rotation angles or a power efficiency of the micro-mirror that defines a ratio of power between first light received in a predetermined window in a far field from the micro-mirror with deformation and second light received in the predetermined window in the far field from the micro-mirror without deformation; adjusting the candidate pixelated pattern based on the one or more first attributes and the one or more second attributes; and based on a predetermined condition being satisfied, generating the mask pattern based on the candidate pixelated pattern.

In some aspects, the method further comprises: applying an objective function to the one or more first attributes to obtain a score, wherein the score is negatively influenced by the one or more first attributes and positively influenced by the one or more second attributes; and adjusting the candidate pixelated pattern based on the score. The predetermined condition comprises at least one of: the score exceeding a threshold or the score reaching a maximum.

In some aspects, the predetermined condition comprises a number of iterations by which the candidate pixelated pattern is adjusted and exceeds a threshold.

In some aspects, the predetermined condition and the adjustment of the candidate pixelated pattern are defined based on an optimization algorithm comprising at least one of: a PSO operation, a gradient descent operation, a quasi-newton method, or a newton method.

In one example, a method of manufacturing a micro-mirror assembly is provided. The method comprises: performing a first etching operation on a back side of a silicon-on-insulator (SOI) wafer comprising a first silicon layer, a second silicon layer, and an insulator layer sandwiched between the first silicon layer and the second silicon layer to form a plurality of reinforcement structures in the insulator layer and in the second silicon layer, the first etching operation being generated based on a mask pattern generated based on an iterative tradeoff operation between power efficiency and moment of inertia; performing a second etching operation of a second wafer to form a walled structure including sidewalls surrounding a cavity; bonding the back side of the SOI wafer on the walled structure to form a stack; and performing a third etching operation on a front side of the SOI wafer to pattern the first silicon layer, the insulator layer, and the second silicon layer into first fingers, second fingers, and a micro-mirror, such that the second fingers are mechanically connected to the micro-mirror and the first fingers and the second fingers are separated by a gap. The micro-mirror is rotatable in the cavity based on an electrostatic force between the first fingers and the second fingers.

In some aspects, the iterative tradeoff operation comprises at least one of: a PSO operation, a gradient descent operation, a quasi-newton method, or a newton method.

### BRIEF DESCRIPTION OF THE DRAWINGS

The detailed description is set forth with reference to the accompanying figures.

FIG. 1 shows an autonomous driving vehicle utilizing aspects of certain examples of the disclosed techniques herein.

FIG. 2A, FIG. 2B, FIG. 2C, and FIG. 2D illustrate examples of a light steering system and properties of internal components of the light steering system, according to certain examples.

FIG. 3A, FIG. 3B, FIG. 3C, and FIG. 3D illustrate example sources of deformation of a micro-mirror and the impact of deformation.

FIG. 4A, FIG. 4B, FIG. 4C, FIG. 4D, and FIG. 4E illustrate example techniques to reduce the deformation of a micro-mirror, according to examples of the present disclosure.

FIG. 5A, FIG. 5B, FIG. 5C, FIG. 5D, and FIG. 5E illustrate example techniques to reduce the deformation of a micro-mirror, according to examples of the present disclosure.

FIG. 6A, FIG. 6B, and FIG. 6C illustrate a method of fabricating a micro-mirror assembly, according to examples of the present disclosure.

FIG. 7 illustrates an example computer system that may be utilized to implement techniques disclosed herein.

### DETAILED DESCRIPTION

In the following description, various examples of a mirror assembly and a light steering transmitter system will be described. For purposes of explanation, specific configurations and details are set forth to provide a thorough understanding of the examples. However, it will be apparent to one skilled in the art that certain examples may be practiced or implemented without every detail disclosed. Furthermore, well-known features may be omitted or simplified to prevent any obfuscation of the novel features described herein.

Light steering can be found in different applications. For example, a Light Detection and Ranging (LiDAR) module of a vehicle may include a light steering system. The light steering system can be part of the transmitter to steer light towards different directions to detect obstacles around the vehicle and to determine the distances between the obstacles and the vehicle, which can be used for autonomous driving. Moreover, a light steering receiver may also include a micro-mirror array to select a direction of incident light to be detected by the receiver, to avoid detecting other unwanted signals. Further, the headlight of a manually driven vehicle can include the light steering transmitter, which can be controlled to focus light towards a particular direction to improve visibility for the driver. In another example, optical diagnostic equipment, such as an endoscope, can include a light steering transmitter to steer light in different directions onto an object in a sequential scanning process to obtain an image of the object for diagnosis.

Light steering can be implemented by way of a micro-mirror array. The micro-mirror array can have an array of micro-mirror assemblies, with each micro-mirror assembly having a movable micro-mirror and an actuator (or multiple actuators). The micro-mirrors and actuators can be formed as microelectromechanical systems (MEMS) on a semiconductor substrate, which allows integration of the MEMS with other circuitries (e.g., controller, interface circuits) on the semiconductor substrate. In a micro-mirror assembly, a micro-mirror can be mechanically connected to the semiconductor substrate via a connection structure (e.g., a torsion bar, a spring) to form a pivot.

A micro-mirror can be rotated around the pivot by an actuator. Each micro-mirror can be rotated by a rotation angle to reflect (and steer) light towards a target direction. The connection structure can be deformed to accommodate the rotation, but the connection structure also has a degree of spring stiffness, which varies with the rotation angle and counters the rotation of the micro-mirror to set a target rotation angle. To rotate a micro-mirror by a target rotation angle, an actuator can apply to the micro-mirror a torque based on the moment of inertia of the mirror, as well as the degree of spring stiffness for a given target rotation angle. Different torques can be applied to the micro-mirror to achieve different target rotation angles. The actuator can then remove the torque, and the connection structure can return the micro-mirror back to its default orientation for the next rotation. The rotation of the micro-mirror can be repeated in the form of an oscillation at a resonant frequency based on the spring constant and the mass of the micro-mirror.

The array of micro-mirrors can receive incident light beams from a light source, which can include a set of collimated light beams, and each micro-mirror can be rotated at a common rotation angle to project/steer the collimated light beams at a target direction. Each micro-mirror can be rotated around two orthogonal axes to provide a first range of angles of projection along a vertical dimension and to provide a second range of angles of projection along a horizontal dimension. The first range and the second range of angles of projection can define a two-dimensional field of view (FOV) in which light is to be projected to detect/scan an object. The FOV can also define a two-dimensional range of directions of incident lights reflected by the object that are to be detected by the receiver.

The array of micro-mirrors can be rotated according to a scanning sequence, with each micro-mirror rotated by the same rotation angle to project the collimated light beams towards different scanning points in the FOV. Each scanning point, which can be defined by a window in the FOV, can receive the same (and maximum) number of light beams. This can maximize the illumination power efficiency, which is defined based on a ratio between a number of the light beams actually received in the window and the number of light beams reflected by the micro-mirror. On the other hand, due to various reasons, such as the micro-mirrors not rotating by the same rotation angle or the light-reflecting surfaces of the micro-mirrors becoming deformed, beam divergence may result. Beam divergence can occur when collimated light beams become divergent when reflected by the micro-mirror, such that the reflected light beams are no longer collimated/focused. Some or all of the scanning points may not receive all of the collimated light beams reflected by the micro-mirror, as some of the light beams reach outside the window of a scanning point. As a result, some or all of the scanning points may receive a reduced number of light beams within their respective windows, which can reduce the illumination power efficiency.

To increase the FOV and/or the detection range, the size of a micro-mirror can be increased to provide a larger aperture, and the range of rotation angle of the micro-mirror can also be increased. But all these can increase the beam divergence caused by the micro-mirror. Specifically, in a case where the micro-mirror only includes a flat structure, as the size of the micro-mirror increases, the structural strength of the micro-mirror can become weakened. As a result, the micro-mirror may be more susceptible to dynamic deformation caused by non-uniform acceleration of different parts of the micro-mirror when the micro-mirror rotates, which increases the beam divergence caused by the micro-mirror. Moreover, the deformation of the connection structure between the micro-mirror and the substrate when the micro-mirror rotates also introduces a deformation force, such as a shear force, that can further deform the micro-mirror and further increase the beam divergence. The deformation force experienced by different parts of the micro-mirror is typically non-uniform, which can lead to a non-uniform distribution of deformation across the micro-mirror.

One way to improve the structural strength of the micro-mirror and to reduce the degree of deformation is by increasing the thickness of the micro-mirror. The micro-mirror can retain a flat structure but with an increased thickness. Such arrangements, however, can substantially increase the overall moment of inertia of the micro-mirror. As a result, a larger driving force is needed to rotate the micro-mirror, which makes the micro-mirror more difficult to control and may increase the complexity of the control algorithm. Moreover, as different parts of the micro-mirror receive different amounts of deformation forces and are susceptible to different degrees of deformation, increasing the thickness indiscriminately across the micro-mirror can lead to over-reinforcement at some locations of the micro-mirror and under-reinforcement at some other locations of the micro-mirror, at the cost of substantial increases in the moment of inertia and driving force for the micro-mirror. Therefore, it is desirable to reinforce the micro-mirror in a way that takes into account the different amounts of deformation forces experienced at different locations of the micro-mirror, such that the resulting reinforcement structures can be effective in reducing the overall deformation of the micro-mirror, while the increase in the moment of inertia introduced by the reinforcement structures can be reduced/minimized.

### Conceptual Overview of Certain Examples

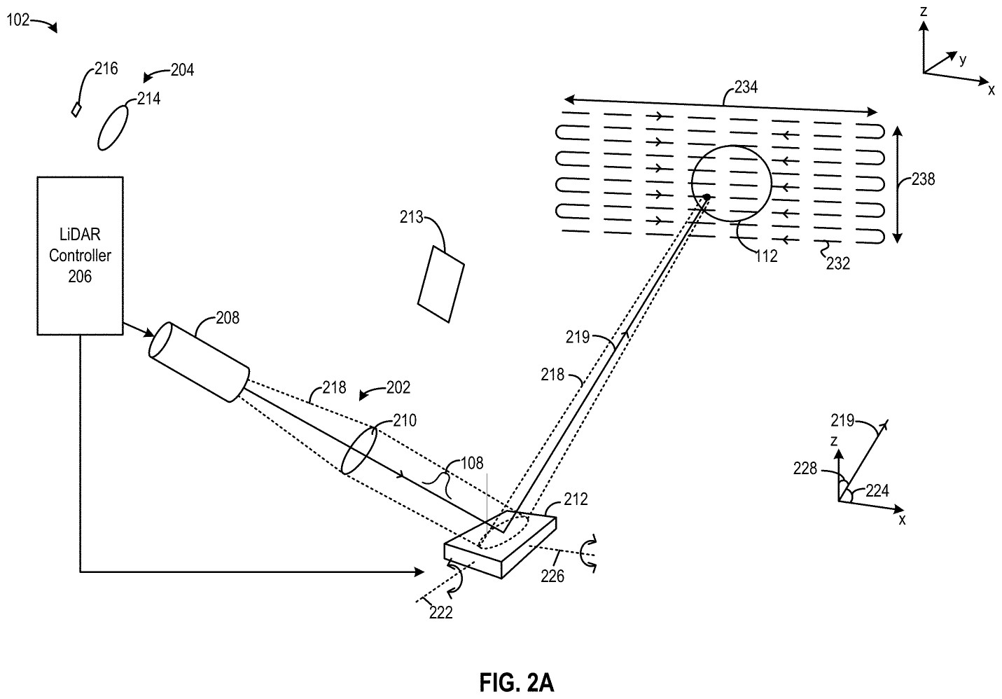

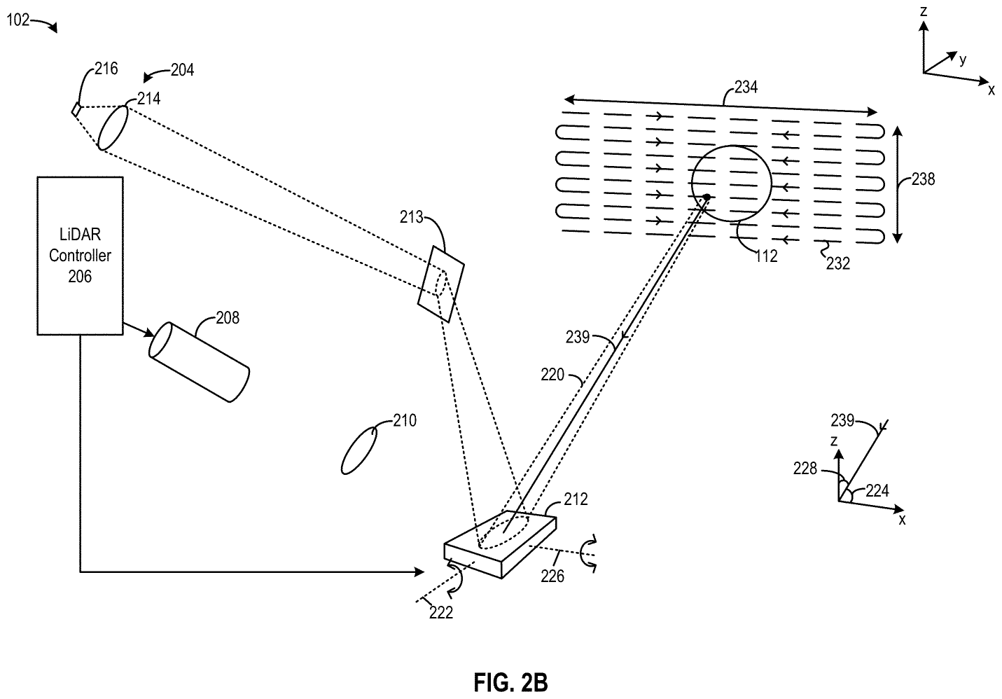

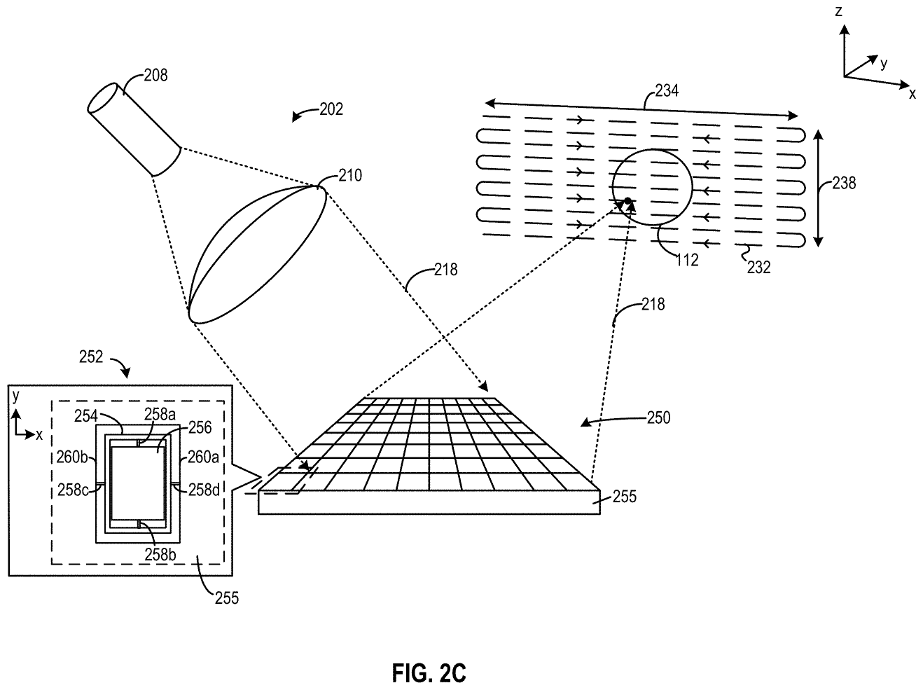

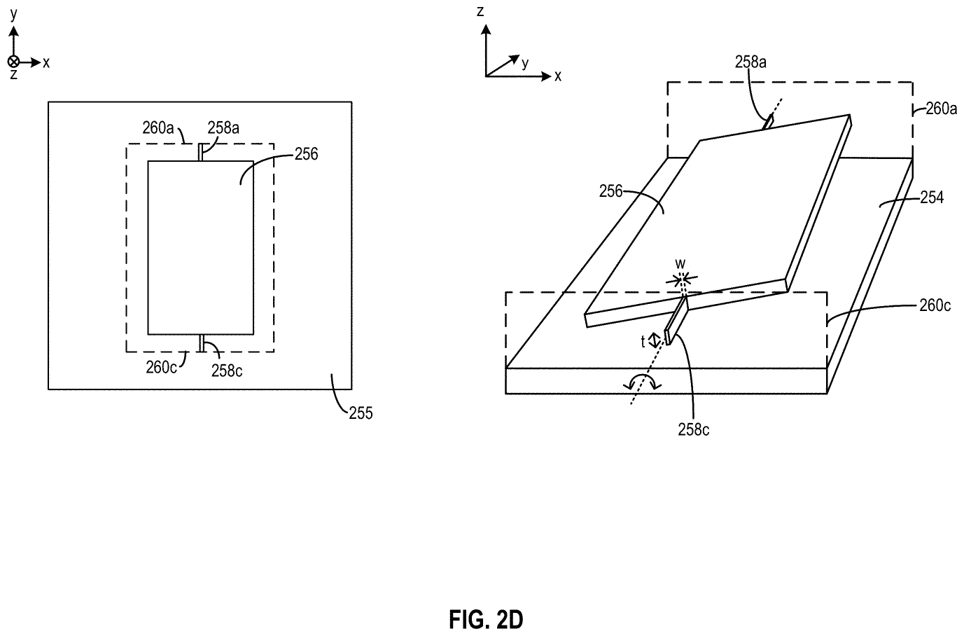

Examples of the present disclosure relate to a light steering system, as well as methods of designing and fabricating a micro-mirror that can address the problems described above. Various examples of the light steering can include a plurality of micro-mirrors to perform light steering, such as those shown and described below with respect to FIG. 2A-FIG. 5E. The light steering system can be used as part of a transmitter to control a direction of projection of output light. The light steering system can also be used as part of a receiver to select a direction of input light to be detected by the receiver. The light steering system can also be used in a coaxial configuration such that the light steering system can project output light to a location and detect light reflected from that location.

In some examples, a light steering system may include a light source, a semiconductor integrated circuit comprising an MEMS and a controller, and a receiver. The MEMS may include an array of micro-mirror assemblies, each micro-mirror assembly comprising a micro-mirror. The micro-mirror assemblies of the MEMS may be configured to reflect light from the light source along an output projection path. The micro-mirror assemblies of the MEMS may also be configured to reflect incident light propagating along an input path to the receiver. In each micro-mirror assembly, the micro-mirror is rotatable around to a pivot according to a rotation angle to reflect (and steer) light towards a target direction in the FOV. Each micro-mirror assembly further includes an actuator controllable by a controller to rotate the micro-mirror.

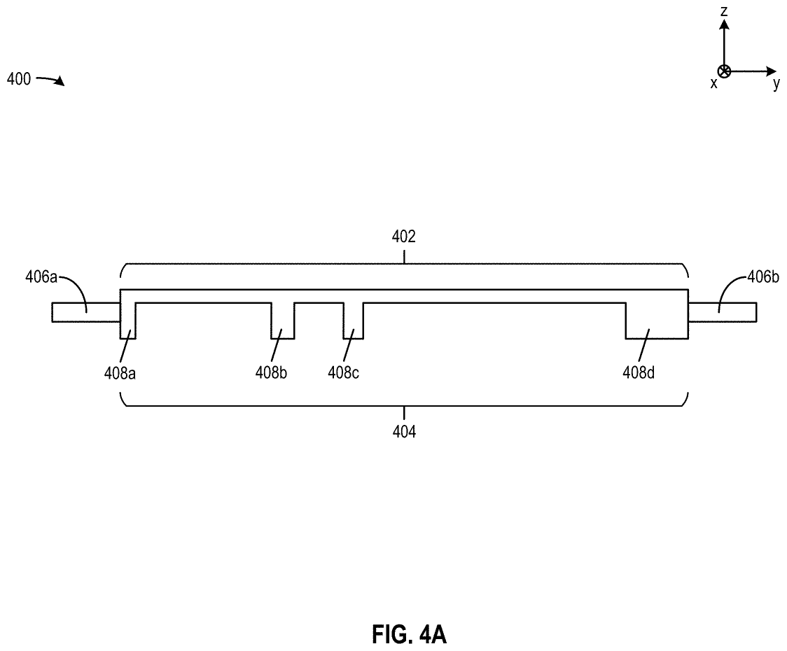

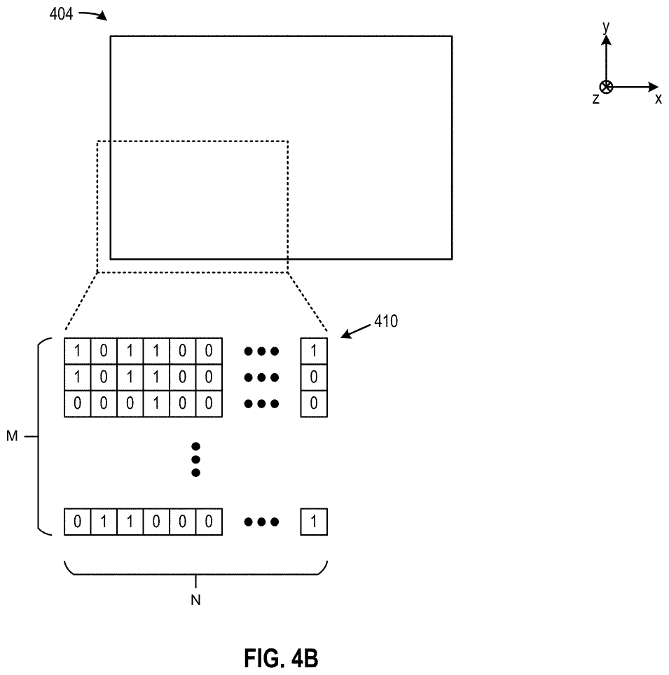

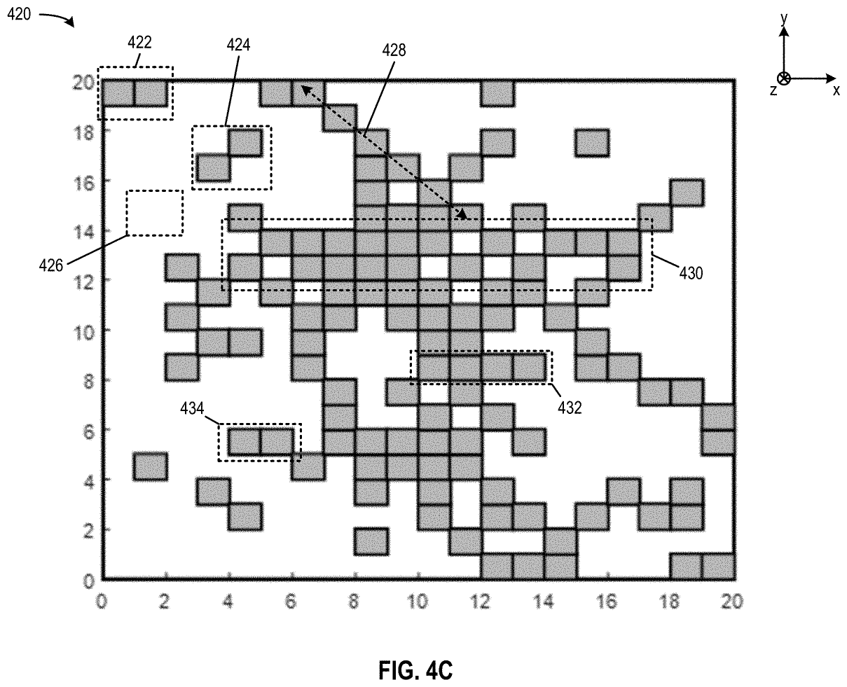

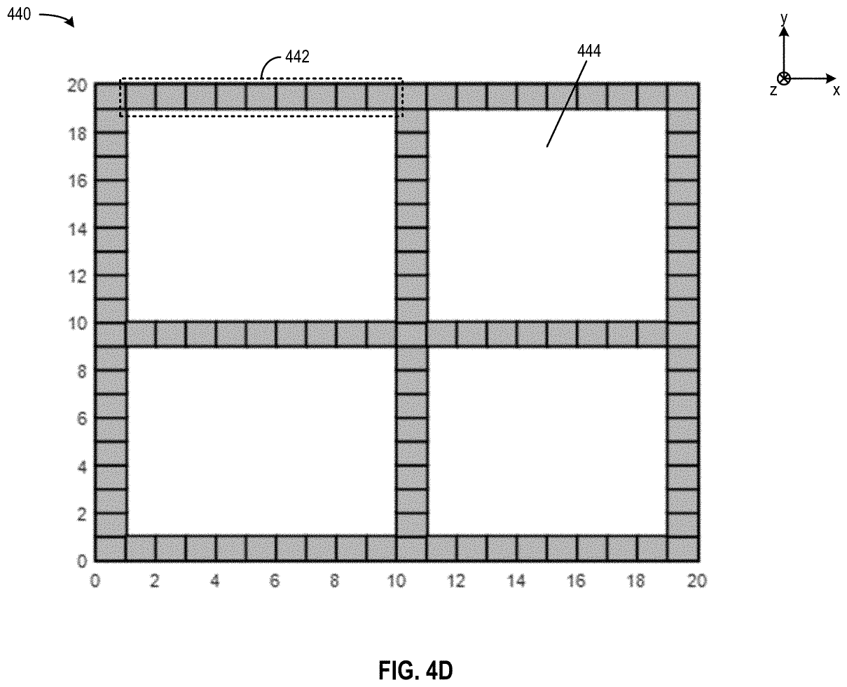

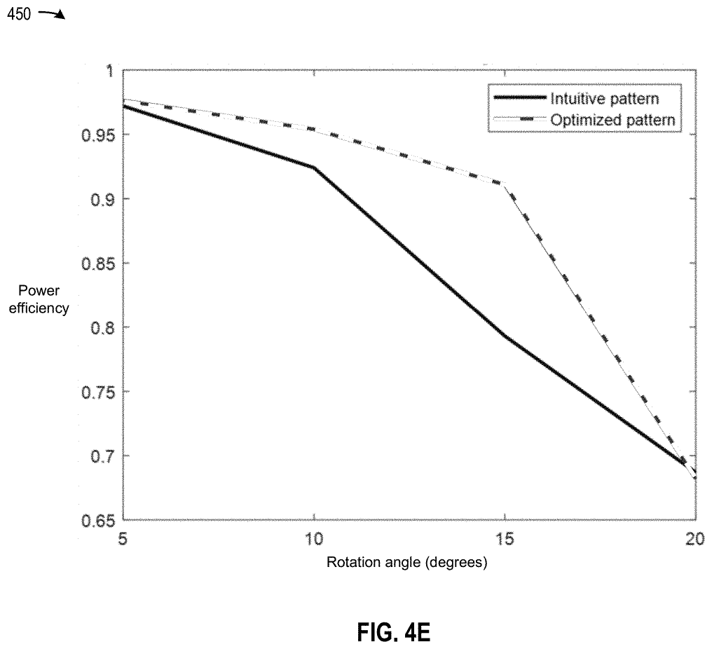

In some examples, the micro-mirror in each micro-mirror assembly can have a flat front side to reflect light, as well as a pixelated pattern of reinforcement structures on a back side. As shown in FIG. 4B, the back side can be divided into an array of pixels, with each pixel corresponding to a particular location/portion of the back side. The pixelated pattern can define whether a protrusion structure that protrudes from the back side is formed at a particular pixel of the back side. Due to the presence/absence of protrusion structure at different locations of the back side of the micro-mirror, the micro-mirror can have uneven thickness. For example, the micro-mirror can have an increased thickness at pixels of the back side that have protrusion structures, and a reduced thickness at pixels of the back side that do not have protrusion structures, as defined by the pixelated pattern. The protrusion structures, having an increased thickness, can become part of the reinforcement structures to improve the structural strength of the micro-mirror. As to be described below, the pixelated pattern can be determined based on a tradeoff between the total moment of inertia and an illumination power efficiency of the micro-mirror. For example, the pixelated pattern can be determined in an iterative process to minimize the degree of deformation, maximize the power efficiency, etc., for a given total moment of inertia.

With the disclosed techniques, a pattern of reinforcement structures can be formed on the back side of the micro-mirror. Compared with the arrangements where the thickness is increased indiscriminately across the micro-mirror, a pattern of reinforcement structures can introduce less increase in the moment of inertia to the micro-mirror. Moreover, by selecting a pattern of reinforcement structures from a set of candidate patterns that minimizes the degree of deformation, maximizes the power efficiency, etc., for a given total moment of inertia, the cost of providing a certain degree of reinforcement to the micro-mirror (moment of inertia and required torque) can be reduced or at least constrained, which can improve the efficiency in reinforcing the micro-mirror. Furthermore, by dividing the micro-mirror's back side into pixels and forming pixelated patterns of reinforcement structures, the granularity of tailoring the pattern reinforcement structures can be improved, which makes it more likely that the pattern of reinforcement structures can match well with the distribution of deformation forces experienced by the micro-mirror. All these can reduce the deformation of the micro-mirror while keeping the cost of the reinforcement low. As a result, the performance of the micro-mirror assembly (e.g., required driving force, beam divergence) can be improved.

Various examples of reinforcement structure patterns are disclosed. FIG. 4C illustrates an example of a pixelated pattern of reinforcement structures. As shown in FIG. 4C, a pixelated pattern of reinforcement structures can include a plurality of non-uniform sub-patterns of reinforcement structures having non-uniform geometric planar shapes, non-uniform planar sizes, non-uniform planar orientations, etc., on the back-side surface of the micro-mirror. The pixelated pattern of reinforcement structure shown in FIG. 4C can be determined such that it minimizes the degree of deformation and/or maximizes the power efficiency for a given total moment of inertia, and the non-uniformity of the reinforcement structures can reflect a distribution of deformation force experienced at different locations of the micro-mirror. FIG. 4D illustrates another example of a pixelated pattern of reinforcement structure, which includes uniform grid-like sub-patterns of reinforcement structures. The uniform sub-patterns of reinforcement structures in FIG. 4D may or may not reflect an optimized tradeoff between power efficiency and moment of inertia, such that the power efficiency of the micro-mirror is not maximized for a given total moment of inertia. For example, as shown in FIG. 4E, at different micro-mirror rotation angles, the pixelated pattern of reinforcement structures in FIG. 4C can provide improved power efficiency (and reduced deformation) compared with the pixelated pattern of reinforcement structures in FIG. 4D.

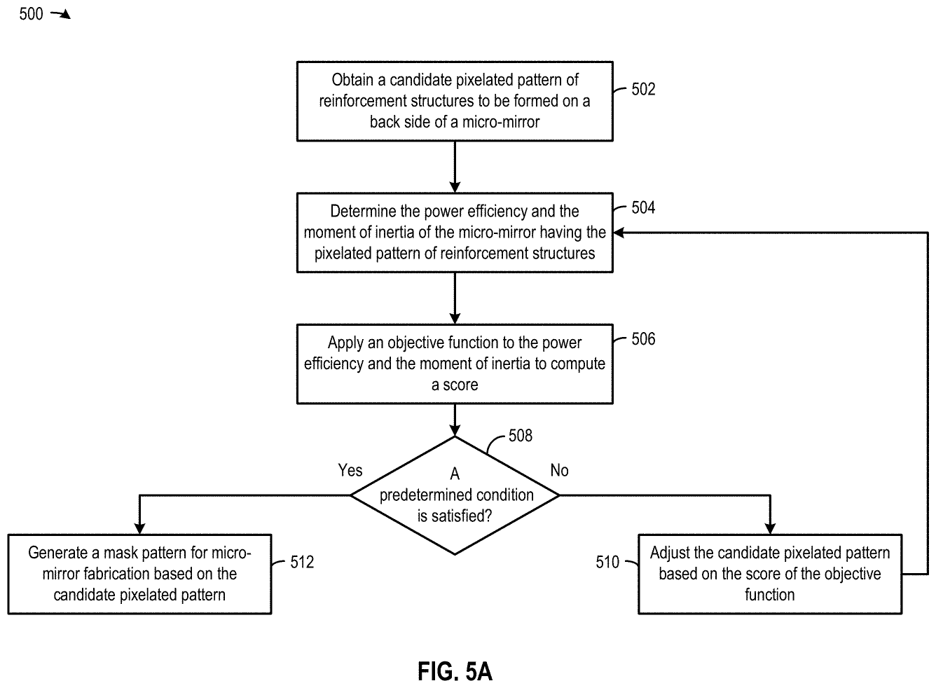

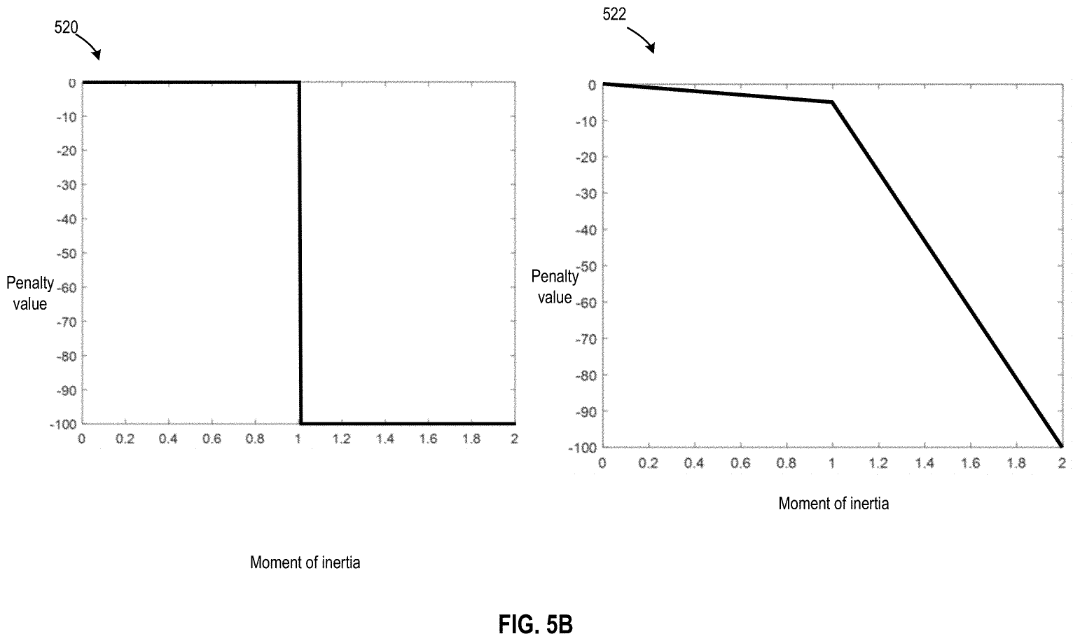

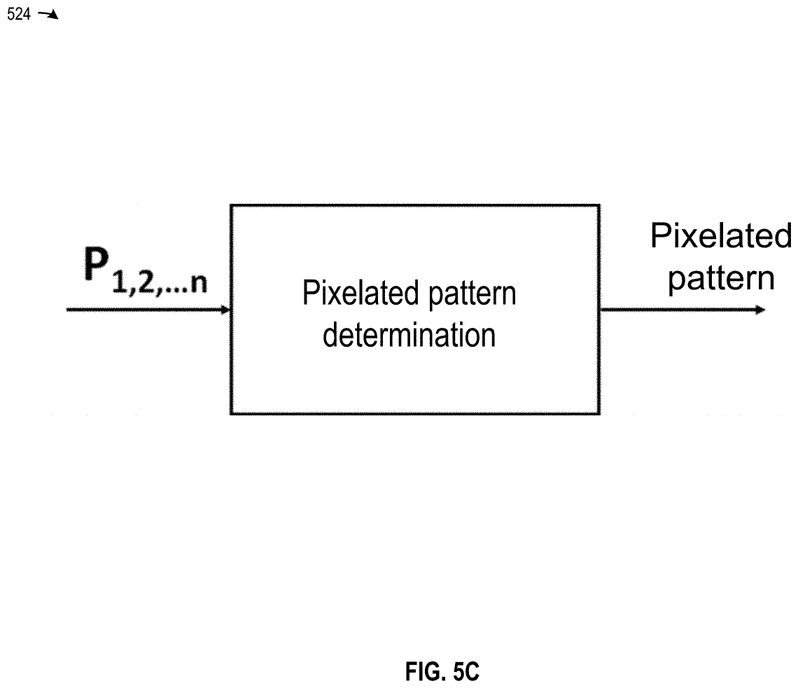

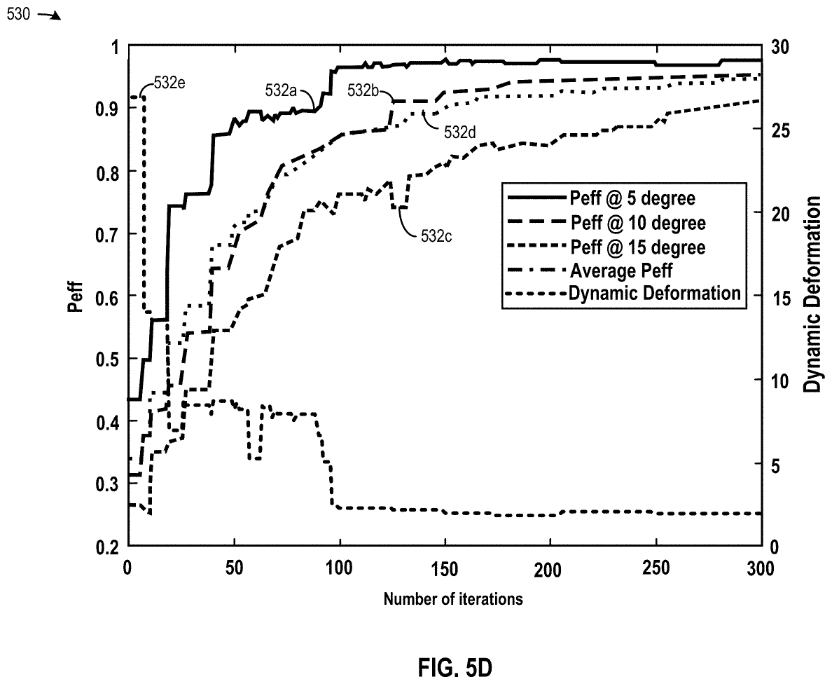

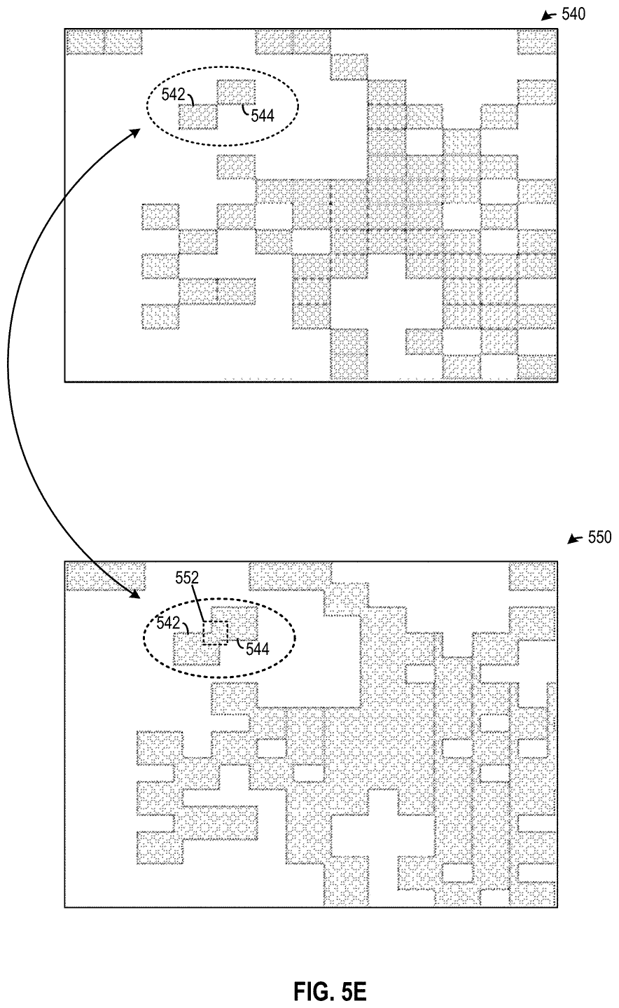

As described above, the pixelated pattern can be determined to minimize the degree of deformation and/or maximize the power efficiency of a micro-mirror for a given total moment of inertia. The pixelated pattern determination process can be an iterative process. An example of the iterative process is illustrated in FIG. 5A. As part of the iterative process, a candidate pixelated pattern of reinforcement structures can be obtained. The candidate pixelated pattern can be any pattern that serves as a starting point. The power efficiency of a micro-mirror having the candidate pixelated pattern can then be computed. As part of the computation, a distribution of degrees of deformation across different locations of the micro-mirror having the candidate pixelated pattern when the micro-mirror is rotated by a certain angle can be determined. The resulting beam divergence and power efficiency of the micro-mirror can then be determined based on the degrees of deformation. The moment of inertia of the micro-mirror having the candidate pixelated pattern can also be computed.

An objective function, which evaluates a tradeoff between the power efficiency and the moment of inertia, can then be applied to the power efficiency and the moment of inertia to compute a score. The score can be positively impacted by the power efficiency and negatively impacted by the moment of inertia. If the score does not satisfy a predetermined condition (e.g., the score exceeding a threshold or reaching a peak), the candidate pixelated pattern can be adjusted based on the score. Various algorithms can be employed to adjust the candidate pixelated pattern, such as a particle swarm optimization (PSO) operation, a gradient descent operation, a quasi-newton method, or a newton method. The power efficiency and the moment of inertia of the micro-mirror having the adjusted pixelated pattern can be computed and reevaluated using the objective function. The adjustment of the candidate pixelated pattern and the evaluation of the pattern can be repeated as part of the iterative process until the score satisfies the condition. Once the score satisfies the condition, the candidate pattern can be used to generate a mask pattern, which can be used to pattern the back side of the micro-mirror to form the reinforcement structures. FIG. 5C illustrates an example pixelated pattern determination process 524 which receives, as an input, power efficiency calculated with distribution of deformation at different locations, moment of inertia and a set of binary parameters represent current pattern as shown in FIG. 4B, then generates a pixelated pattern (also represented by a set of binary parameters) of reinforcement structure based on the input.

In some examples, the array of micro-mirror assemblies can be implemented in a silicon-on-insulator (SOI) wafer comprising a first silicon layer, a second silicon layer, and an insulator layer (e.g., silicon dioxide) sandwiched between the first silicon layer and the second silicon layer. The insulator and the second silicon layer can be patterned by a back-side etching process, using the mask pattern generated from the iterative process described above, to form a pattern of reinforcement structures underneath the micro-mirror. While the patterned SOI wafer is bonded to a handle wafer, a front-side etching process can be performed on the front side of the SOI wafer. The first silicon layer can be patterned to form the micro-mirror, the frame, the gimbal, the first set of fingers, and the second set of fingers of each micro-mirror assembly.

### Typical System Environment for Certain Examples

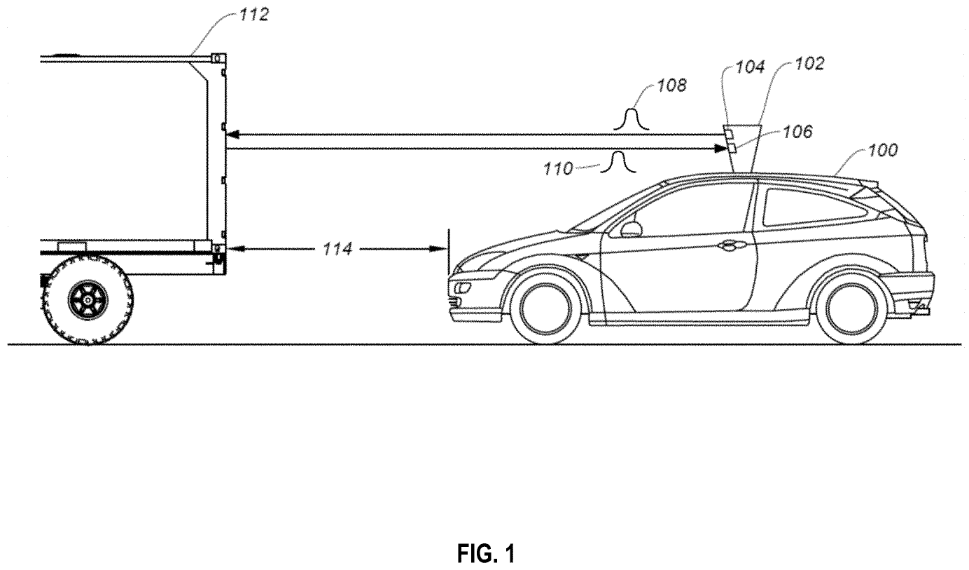

FIG. 1 illustrates an autonomous vehicle 100 in which the disclosed techniques can be implemented. Autonomous vehicle 100 includes a LiDAR module 102. LiDAR module 102 allows autonomous vehicle 100 to perform object detection and ranging in a surrounding environment. Based on the result of object detection and ranging, autonomous vehicle 100 can maneuver to avoid a collision with the object. LiDAR module 102 can include a light steering transmitter 104 and a receiver 106. Light steering transmitter 104 can project one or more light signals 108 at various directions at different times in any suitable scanning pattern, while receiver 106 can monitor for a light signal 110 which is generated by the reflection of light signal 108 by an object. Light signals 108 and 110 may include, for example, a light pulse, a frequency modulated continuous wave (FMCW) signal, or an amplitude modulated continuous wave (AMCW) signal. LiDAR module 102 can detect the object based on the reception of light pulse 110 and can perform a ranging determination (e.g., a distance of the object) based on a time difference between light signals 108 and 110. For example, as shown in FIG. 1, LiDAR module 102 can transmit light signal 108 at a direction directly in front of autonomous vehicle 100 at time T1 and receive light signal 110 reflected by an object 112 (e.g., another vehicle) at time T2. Based on the reception of light signal 110, LiDAR module 102 can determine that object 112 is directly in front of autonomous vehicle 100. Moreover, based on the time difference between T1 and T2, LiDAR module 102 can also determine a distance 114 between autonomous vehicle 100 and object 112. Autonomous vehicle 100 can adjust its speed (e.g., by slowing or stopping) to avoid collision with object 112 based on the detection and ranging of object 112 by LiDAR module 102.

FIG. 2A-FIG. 2C illustrate examples of internal components of a LiDAR module 102. LiDAR module 102 includes a transmitter 202, a receiver 204, and a LiDAR controller 206 which controls the operations of transmitter 202 and receiver 204. Transmitter 202 includes a light source 208 and a collimator lens 210, whereas receiver 204 includes a lens 214 and a photodetector 216. LiDAR module 102 further includes a mirror assembly 212. LiDAR module 102 may further include a beam splitter 213. In LiDAR module 102, transmitter 202 and receiver 204 can be configured as a coaxial system to share mirror assembly 212 to perform light steering operation, with beam splitter 213 configured to reflect incident light reflected by mirror assembly 212 to receiver 204.

FIG. 2A illustrates a light projection operation. To project light, LiDAR controller 206 can control light source 208 (e.g., a pulsed laser diode, a source of FMCW signal, AMCW signal) to transmit light signal 108 as part of light beam 218. Light beam 218 can disperse upon leaving light source 208 and can be converted into collimated light beam 218 by collimator lens 210. Collimated light beam 218 can be incident upon a mirror assembly 212, which can reflect collimated light 218 to steer it along an output projection path 219 towards object 112. Mirror assembly 212 can include one or more rotatable mirrors. FIG. 2A illustrates mirror assembly 212 as having one mirror, but as to be described below, a micro-mirror array comprising multiple micro-mirror assemblies can be used to provide the steering capability of mirror assembly 212. Mirror assembly 212 further includes one or more actuators (not shown in FIG. 2A) to rotate the rotatable mirrors. The actuators can rotate the rotatable mirrors around a first axis 222 and can rotate the rotatable mirrors along a second axis 226. The rotation around first axis 222 can change a first angle 224 of output projection path 219 with respect to a first dimension (e.g., the x-axis), whereas the rotation around second axis 226 can change a second angle 228 of output projection path 219 with respect to a second dimension (e.g., the z-axis). LiDAR controller 206 can control the actuators to produce different combinations of angles of rotation around first axis 222 and second axis 226 such that the movement of output projection path 219 can follow a scanning pattern 232. A range 234 of movement of output projection path 219 along the x-axis, as well as a range 238 of movement of output projection path 219 along the z-axis, can define an FOV. An object within the FOV, such as object 112, can receive and reflect collimated light beam 218 to form reflected light signal, which can be received by receiver 204.

FIG. 2B illustrates a light detection operation. LiDAR controller 206 can select an incident light direction 239 for detection of incident light by receiver 204. The selection can be based on setting the angles of rotation of the rotatable mirrors of mirror assembly 212 such that only light beam 220 propagating along light direction 239 gets reflected to beam splitter 213, which can then divert light beam 220 to photodetector 216 via collimator lens 214. With such arrangements, receiver 204 can selectively receive signals that are relevant for the ranging/imaging of object 112, such as light signal 110 generated by the reflection of collimated light beam 218 by object 112, and not receive other signals. As a result, the effect of environment disturbance on the ranging/imaging of the object can be reduced and the system performance can be improved.

FIG. 2C illustrates an example of a micro-mirror array 250 that can be part of light steering transmitter 202 and can provide the steering capability of mirror assembly 212. Micro-mirror array 250 can include an array of micro-mirror assemblies, including micro-mirror assembly 252. Micro-mirror assembly 252 can include an MEMS implemented on a semiconductor substrate 255. Micro-mirror assembly 252 may include a frame 254 and a micro-mirror 256 forming a gimbal structure. Specifically, connection structures 258a and 258b connect micro-mirror 256 to frame 254, whereas connection structures 258c and 258d connect frame 254 (and micro-mirror 256) to sidewalls 260a and 260b semiconductor substrate 255 at a pair of pivot points. A pair of connection structures can define a pivot/axis of rotation for micro-mirror 256. For example, connection structures 258a and 258b can define a pivot/axis of rotation of micro-mirror 256 about the y-axis within frame 254, whereas connection structures 258c and 258d can define a pivot/axis of rotation of frame 254 and micro-mirror 256 about the x-axis with respect to semiconductor substrate 255.

A micro-mirror assembly 252 can receive and reflect part of light beam 218. Micro-mirror 256 of micro-mirror assembly 252 can be rotated by an actuator of the micro-mirror assembly (not shown in FIG. 2B) at a first angle about the y-axis (around connection structures 258a and 258b) and at a second angle about the x-axis (around connection structures 258c and 258d) to set the direction of output projection path for light beam 218 and to define the FOV, as in FIG. 2A, or to select the direction of input light to be detected by receiver 204, as in FIG. 2B. FIG. 2C illustrates another view of micro-mirror assembly 252 including connection structures 258a and 256c having a width w and a thickness H.

To accommodate the rotation motion of mirror 256, connection structures 258a, 258b, 258c, and 258d are configured to be elastic and deformable. The connection structure can be in the form of, for example, a torsion bar or a spring and can have a certain spring stiffness. The spring stiffness of the connection structure can define a torque required to rotate mirror 256 by a certain rotation angle, as follows:

τ=−Kθ. (Equation 1)

In Equation 1, τ represents torque and K represents a spring constant that measures the spring stiffness of the connection structure, whereas θ represents a target angle of rotation. The spring constant can depend on various factors, such as the material of the connection structure or the cross-sectional area of the connection structure. For example, the spring constant can be defined according to the following equation:

$$K = \frac{{k}_{2} \times G \times {w}^{3} \times t}{L} . \qquad ( Equation 2 )$$

In Equation 2, L is the length of the connection structure, G is the shear modulus of material that forms the connection structure, and k₂ is a factor that depends on the ratio between thickness (t) and width (w) given as t/w.

Based on Equations 1 and 2, different torques can be applied to the micro-mirror to achieve different target rotation angles to start the rotation. The actuator can then remove the torque, and the elasticity of the connection structure, defined by the spring constant, can return micro-mirror 256 back to its default orientation to begin the next rotation. The rotation of micro-mirror 256 can be repeated in the form of oscillation. When in a steady state, micro-mirror 256 can rotate at a resonant frequency ω based on the spring constant of connection structures 258a-d as well as the mass of micro-mirror 256, as follows:

$$ω = \sqrt{\frac{K}{J}} . \qquad ( Equation 3 )$$

In Equation 3, K is the spring constant of connection structures 258a-d, whereas J is the moment of inertia of micro-mirror 256. The actuator can apply and then remove a torque at the natural frequency of the micro-mirror to maintain the oscillation. During steady state, a torque can be applied at the resonant frequency to overcome the damping to the oscillation. The damping can be caused by various sources, such as air friction encountered by the micro-mirror as the micro-mirror rotates, which introduces air damping.

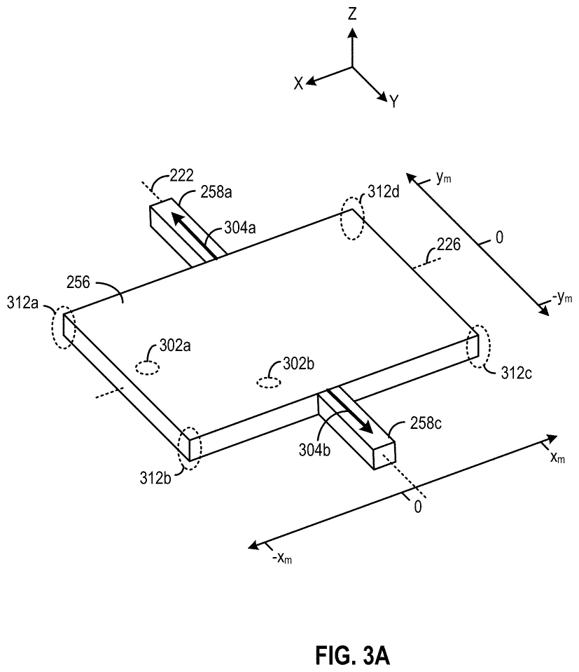

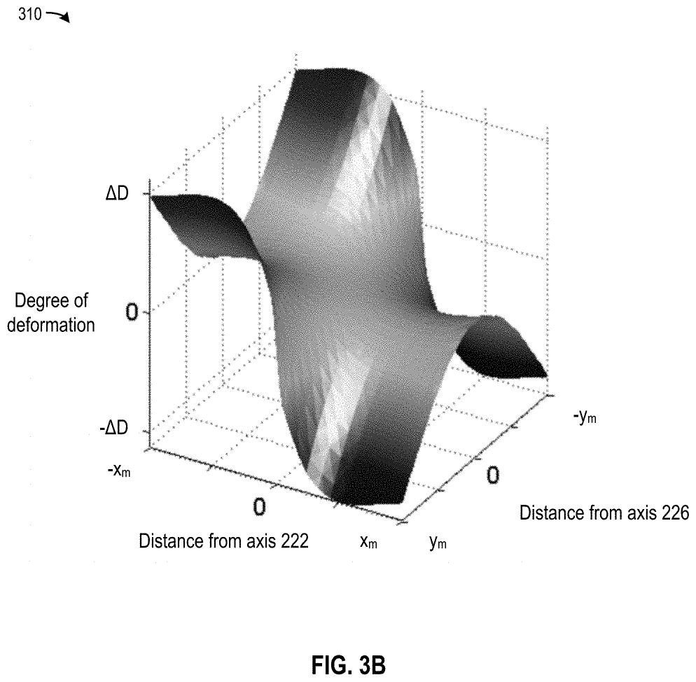

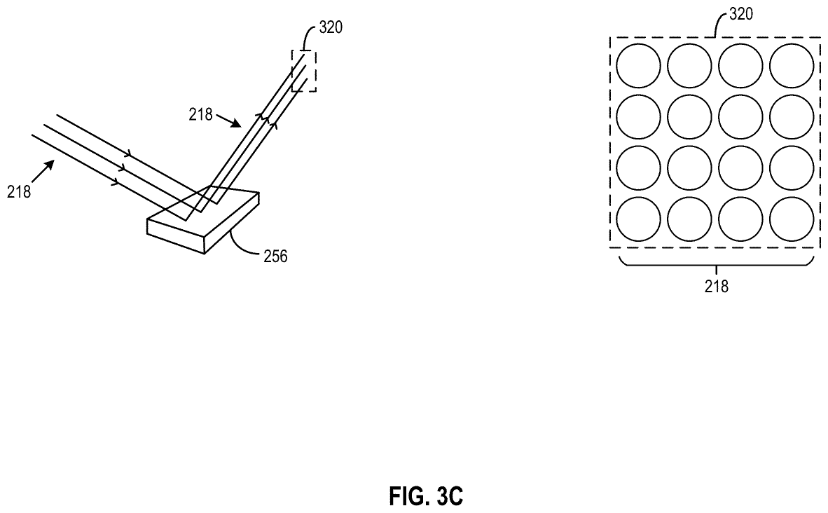

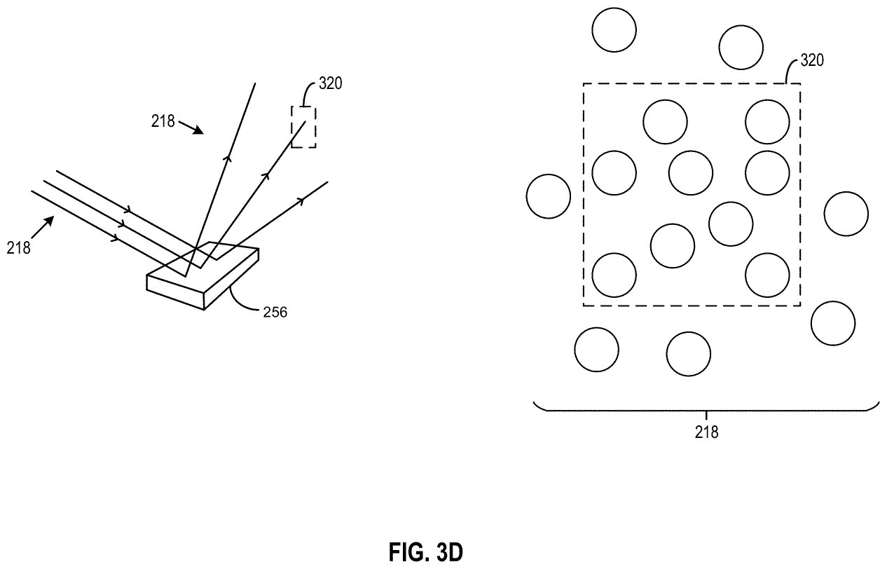

As described above, when micro-mirror 256 rotates, micro-mirror 256 may be susceptible to deformation such that its light-reflecting surface is no longer flat. FIG. 3A illustrates example causes of deformation of micro-mirror 256. Specifically, as micro-mirror 256 rotates in response to a torque, different parts of micro-mirror 256, such as parts 302a and 302b, may have similar angular accelerations but different moments of inertia, as different parts of micro-mirror 256 may have different distance from rotation axis 222, which can lead to different linear speed and linear accelerations, and different moments of inertia. The different moments of inertia can create different torsional loads at different parts of the micro-mirror, which can create deformation forces. In addition, as connection structures 258a and 258c deform to accommodate the rotation of micro-mirror 256, the deformation can introduce a shear force, such as shear forces 304a and 304b. The shear forces can be transmitted over micro-mirror 256 and can also create deformation.

Due to the different moments of inertia as well as different shear forces, the deformation forces experienced by different parts of the micro-mirror are typically non-uniform. Because of the non-uniform deformation force, if micro-mirror 256 has an evenly distributed stiffness, the micro-mirror can have non-uniform degrees of deformation, which leads to an overall deformation of the micro-mirror. FIG. 3B illustrates a graph 310 of a spatial distribution of degrees of deformation across micro-mirror 256 with respect to distances from first axis 222 and second axis 226. As shown in FIG. 3B, different locations of micro-mirror 256 have different degrees of deformation. The degree of deformation can be of the highest (+/−AD) at the four corners 312a, 312b, 312c, and 312d of micro-mirror 256 and can be of the minimum (close to zero) along first axis 222 and second axis 226. Notice that FIG. 3B is provided as example only, and the spatial distribution of deformation can vary. For example, a micro-mirror of a different size or shape and/or having a connection mechanism with the substrate (e.g., being connected to the substrate via a gimbal frame, having a different type of connection structure) can have a very different spatial distribution of deformation from the example depicted in FIG. 3B.

The non-uniform deformation of micro-mirror 256 can cause beam divergence such that the reflected light beams (from incident collimated light beams) are no longer collimated. FIG. 3C and FIG. 3D illustrate the effects of beam divergence. As shown in FIG. 3C, in a case where micro-mirror 256 is perfectly flat, each of incident light beams 218 has the same incident angle with respect to the same flat surface of micro-mirror 256 and therefore can also be reflected by the same reflection angle towards a window 320 in the FOV. As a result, if incident light beams 218 are collimated when they are incident upon micro-mirror 256, the reflected light beams 218 can remain collimated and window 320 can receive the same number of incident light beams 218 reflected by micro-mirror 256 (e.g., 16 of them in FIG. 3C). This can maximize the illumination power efficiency of micro-mirror 256.

Referring to FIG. 3D, in a case where micro-mirror 256 experiences varying degrees of deformation at different locations, micro-mirror 256 is no longer perfectly flat. As a result, each of incident light beams 218 may have different incident angles with respect to different deformed surfaces of micro-mirror 256 and therefore can be reflected by different reflection angles towards window 320 in the FOV, leading to divergence of the reflected light beams 218. As a result, window 320 can receive a lower number of incident light beams 218 than those reflected by micro-mirror 256 (e.g., 9 of them in FIG. 3D). This can reduce the illumination power efficiency of micro-mirror 256.

One way to improve the structural strength of the micro-mirror and to reduce the degree of deformation is by increasing the thickness of the micro-mirror. The micro-mirror can retain a flat structure but with an increased thickness. Such arrangements, however, can substantially increase the overall moment of inertia of the micro-mirror. As a result, a larger driving force is needed to rotate the micro-mirror, which makes the micro-mirror more difficult to control and may increase the complexity of the control algorithm. Moreover, as different parts of the micro-mirror receive different amounts of deformation forces and are susceptible to different degrees of deformation, increasing the thickness indiscriminately across the micro-mirror can lead to over-reinforcement at some locations of the micro-mirror and under-reinforcement at some other locations of the micro-mirror, at the cost of substantial increases in the moment of inertia and driving force for the micro-mirror.

### Example Techniques to Improve Structural Strength of a Micro-Mirror

FIG. 4A, FIG. 4B, FIG. 4C, and FIG. 4D illustrate examples of a micro-mirror that can address at least some of the issues described above. FIG. 4A illustrates a side view of a micro-mirror 400. As shown in FIG. 4A, micro-mirror 400 can have a front-side light-reflecting surface 402, a back side 404, and a pair of connection structures 406a and 406b. Micro-mirror 400 can have a pattern of reinforcement structures 408, including structures 408a, 408b, 408c, and 408d, formed at different locations of back side 404. Reinforcement structures 408 can be in the form of protrusion structures to increase the thickness as well as structural strength of micro-mirror 400. In some examples, micro-mirror 400 can have a thickness of 80 micrometers (um) (along the z-axis) at locations that do not have the protrusion structures, and a thickness of 580 um at locations that have the protrusion structures. As the thickness of micro-mirror 400 is not uniformly increased, the increase in the moment of inertia caused by reinforcement structures 408 can be reduced. Moreover, as to be described below, reinforcement structures 408 can be strategically positioned at certain locations of micro-mirror 400 based on a tradeoff between a degree of deformation (and the resulting power efficiency) and total moment of inertia, to improve/maximize the efficiency in reinforcing micro-mirror 400.

In some examples, reinforcement structures 408 can be defined based on a pixelated pattern. FIG. 4B illustrates an example of a pixelated pattern 410. Referring to FIG. 4B, back side 404 (or part of it) can be divided into an M×N array of pixels, with each pixel corresponding to a particular location/portion of back side 404. A pixelated pattern 410 of reinforcement structures can be defined for the M×N array of pixels, with a pixel value of “1” indicating that a protrusion structure is to be formed on part of back side 404 represented by the pixel, whereas a pixel value of “0” can indicate that no protrusion structure is formed. In some examples, back side 404 can be divided into four quadrants, with each quadrant represented by a 20×20 array of pixels. The same (or different) pixelated pattern 410 of reinforcement structures can be defined for each 20×20 array of pixels.

FIG. 4C illustrates another example of pixelated pattern 420 defined over a 20×20 array of pixels. In FIG. 4C, shaded pixels, such as pixels 422 and 424, represent pixels having protrusion structures (e.g., having a value of “1” as in FIG. 4B), whereas blank areas, such as blank area 426, represent pixels having no protrusion structures (having a value of “0” as in FIG. 4B). Pixelated pattern 420 can include a plurality of non-uniform sub-patterns of reinforcement structures having non-uniform geometric planar shapes, non-uniform planar sizes, non-uniform planar orientations, etc. (on the x-y plane) on the back side of the micro-mirror. For example, pixelated pattern 420 can include a reinforcement structure of pixels 428 forming a slanted line with respect to another reinforcement structure of other pixels, such as pixels 430. Moreover, some of the reinforcement structures, such as those of pixels 422 and 424, have no connecting reinforcement structures in between. In addition, pixelated pattern 420 may include reinforcement structures having a non-uniform width (e.g., measured along the y-axis) that spans different numbers of pixels, such as those of pixels 430, as well as parallel reinforcement structures having different lengths, such as those of pixels 432 and 434.

FIG. 4D illustrates another example of a pixelated pattern 440 of reinforcement structures. Just like pixelated pattern 420 of FIG. 4C, in FIG. 4D, shaded pixels, such as pixels 442, represent pixels having protrusion structures, whereas blank areas, such as blank area 444, represent pixels having no protrusion structure. Pixelated pattern 440 can include uniform grid-like sub-patterns of reinforcement structures, including rows and columns (on the x-y plane) of reinforcement structures having uniform lengths and widths.

Both pixelated patterns 420 and 440 can be determined based on a tradeoff between the total moment of inertia and a power efficiency in the illumination by the micro-mirror. For example, the pixelated pattern can be determined in an iterative process to minimize the degree of deformation, maximize the power efficiency, etc. for a given total moment of inertia. The result of the tradeoff can be different for different total moment of inertia constraints or for different spatial distribution of deformation. For example, as described above, a micro-mirror of a different size or shape and/or having a connection mechanism with the substrate (e.g., being connected to the substrate via a gimbal frame, having a different type of connection structure) can have a very different spatial distribution of deformation from the example depicted in FIG. 3B. Therefore, different pixelated patterns may provide different degrees of reinforcement for a particular micro-mirror assembly.

FIG. 4E illustrates a chart 450 which compares the power efficiency (which relates to a degree of deformation) of a micro-mirror assembly having back-side reinforcement structures formed according to pixelated patterns 420 and 440. The micro-mirror assembly may be similar to micro-mirror assembly 252 of FIG. 2C in which the micro-mirror is connected to a gimbal/frame 254, and gimbal/frame 254 is connected to the substrate via connection structures. Within chart 450, graph 452 illustrates the power efficiency of a micro-mirror assembly having back-side reinforcement structures formed according to pixelated patterns 420 at different rotation angles, whereas graph 454 illustrates the power efficiency of a micro-mirror assembly having back-side reinforcement structures formed according to pixelated patterns 440 at different rotation angles. As shown in FIG. 4E, within a range of rotation angles between 5 to 20 degrees, pixelated pattern 420 can provide a higher power efficiency (and less deformation) than pixelated pattern 440.

### Example Techniques to Determine Pixelated Patterns of Reinforcement Structures

As described above, the pixelated pattern can be determined based on a tradeoff between the total moment of inertia and a power efficiency in the illumination by the micro-mirror. FIG. 5A illustrates an example of an iterative process 500 to determine a pixelated pattern of reinforcement structures. The iterative process can seek to determine a pixelated pattern that minimizes the degree of deformation and/or maximize the power efficiency of a micro-mirror for a given total moment of inertia. Iterative process 500 can be performed by a computer. As shown in FIG. 5A, iterative process 500 can start with step 502, in which a candidate pixelated pattern is obtained. The candidate pixelated pattern can be a starting pattern (e.g., a pattern having all pixels set to zero (no protrusion structures) or one (having a protrusion structure)), a random mixture of pixels having ones and zeros, or a pixelated pattern previously generated by iterative process 500.

In step 504, the power efficiency and the moment of inertia of a micro-mirror having the candidate pixelated pattern can be determined. Different power efficiency values can be computed for different rotation angles. As described above, the power efficiency can reflect a degree of deformation of the micro-mirror at a particular rotation angle, and the degree of deformation can be specific to the size and shape of the micro-mirror as well as the connection mechanisms between the micro-mirror and the substrate (e.g., the connection structure, whether the micro-mirror is directly connected to the substrate or via a gimbal/frame). In some examples, a finite element analysis (FEA) can be performed to compute a distribution of deformation forces received by different locations of the micro-mirror when the micro-mirror rotates by a particular rotation angle. A distribution of degrees of deformation experienced by the different locations of the micro-mirror, having the candidate pixelated pattern of reinforcement structures, can be computed based on the deformation forces. Based on the distribution of deformation, the beam divergence property of the micro-mirror, as well as the power efficiency, can be determined. In addition, the moment of inertia can be determined based on summing the moment of the micro-mirror at each pixel having the reinforcement structures according to the candidate pixelated pattern, as follows:

J=Σᵢ₌₀^{P}(mᵢ×rᵢ²). (Equation 4)

In Equation 4, J is the moment of inertia and mᵢ represents the mass of the micro-mirror at a particular pixel, whereas rᵢ represents the distance of that pixel from the rotation axis, summed over all the pixels 0 to P defined in the candidate pixelated pattern.

In some examples, instead of directly computing the moment of inertia, the total number of pixels having the protrusion structures can be determined from the candidate pattern.

In step 506, an objective function can be applied to the power efficiency and the moment of inertia (or total number of pixels having the protrusion structures) to compute a score. The objective function can evaluate a tradeoff between the power efficiency and the moment of inertia. The score can be positively impacted by the power efficiency and negatively impacted by the moment of inertia.

One example of the objective function can be as follows:

Score=1/3(Peffₛ+Peff₁₀+Peff₁₅)+F. (Equation 5)

In Equation 5, Peff₅, Peff₁₀, and Peff₁₅ represent the power efficiency of the micro-mirror having rotated by an angle of, respectively, 5 degrees, 10 degrees, and 15 degrees. The score increases with the power efficiency values. On the other hand, F can represent a penalty function which can reduce the score, and the degree of reduction increases with the moment of inertia (or the number of pixels having protrusion structures).

FIG. 5B illustrates charts 520 and 522 showing different examples of penalty function F. In chart 520, penalty function F can be in the form of a step function where there is no penalty (with a penalty value of zero) if the moment of inertia is below 1 and there is a maximum penalty (with penalty value of −100) if the moment of inertia reaches or goes beyond 1. On the other hand, in chart 522, penalty function F can be in the form of a piecewise function, in which the penalty value increases with the moment of inertia and the rate of change increases when the moment of inertia reaches or goes beyond 1. The step function of chart 520 can effectively limit the moment of inertia to 1 to reduce the number of candidate pixelated patterns to be considered, which can speed up the determination of the pixelated pattern. But the reduction of the number of possible pixelated patterns can reduce the likelihood of finding a pattern that provides an optimal tradeoff between power efficiency and moment of inertia. On the other hand, the piecewise function of chart 522 allows a larger number of candidate pixelated patterns to be considered, which can increase the likelihood of finding an optimal pattern but at the cost of slowing down the determination process.

Referring back to FIG. 5A, in step 508, it is determined whether a predetermined condition is satisfied, and if not, the candidate pixelated pattern can be adjusted based on the score of the objective function, in step 510. FIG. 5C illustrates additional details of step 510. As shown in FIG. 5C, a pixelated pattern determination algorithm 524 receives, as an input, power efficiency calculated with distribution of deformation at different locations, moment of inertia and a set of binary parameters represent current pattern as shown in FIG. 4B, then generates a pixelated pattern of reinforcement structure (also represented by a set of binary parameters) based on the input. The determination algorithm can have memory about previous pattern that gives best score calculated with an objective function (e.g. with moment of inertia and power efficiency), and generate the new pattern by comparing these information with various algorithm. Then steps 504 and 506 can be repeated based on the adjusted candidate pixelated pattern in a second iteration.

The predetermined condition in step 510, as well as the adjustment of the candidate pixelated pattern in step 512, can be based on various optimization algorithms. One example optimization algorithm is a PSO algorithm. PSO is a computational method that optimizes a problem by iteratively trying to improve a candidate solution with regard to a given measure of quality. It solves a problem by having a population of candidate solutions, here dubbed particles, and moving these particles around in the search-space according to simple mathematical formulae over the particle's position and velocity. Each particle's movement is influenced by its local best-known position but is also guided toward the best-known positions in the search-space, which are updated as better positions are found by other particles.

An example PSO algorithm is provided below:

```
for each particle i = 1, ..., S do
  Initialize the particle’s position with a random vector: xᵢ ~ U(bₗₒ, bᵤₚ)
  Initialize the particle’s best-known position to its initial position: pᵢ ← xᵢ
  if ƒ(pᵢ) < ƒ(g) then
    update the swarm’s best-known position: g ← pᵢ
  Initialize the particle’s velocity: vᵢ ~ U(-|bᵤₚ-bₗₒ|, |bᵤₚ-bₗₒ|)
while a termination criterion is not met do:
  for each particle i = 1, ..., S do
    for each dimension d = 1, ..., n do
      Pick random numbers: rₚ, r_{g} ~ U(0,1)
      Update the particle’s velocity: v_{i,d} ← ω v_{i,d} + φₚ rₚ (p_{i,d}-x_{i,d}) + φ_{g} r_{g} (g_{d}-x_{i,d})
    Update the particle’s position: xᵢ ← xᵢ + lr vᵢ
    if ƒ(xᵢ) < ƒ(pᵢ) then
      Update the particle’s best-known position: pᵢ ← xᵢ
      if ƒ(pᵢ) < ƒ(g) then
        Update the swarm’s best-known position: g ← pᵢ
```

In the PSO algorithm above, U represents a random function and the values bₗₒ and bᵤₚ can represent the lower and upper boundaries of the search-space respectively, whereas f is the objective function, an example of which is defined in Equation 5 above. The termination criterion can be the number of iterations performed, or a solution where the adequate objective function value is found. The parameters ω, φₚ and φ_{g} can be chosen to improve the optimization performance of the PSO algorithm.

Applying the PSO algorithm to iterative process 500, each particle can represent a set of pixels having a pattern of protrusion structures, and its initial location can determined based on a random vector. The values bₗₒ and bᵤₚ can be defined by the boundary of the M×N array of pixels. The termination criterion can correspond to the predetermined condition of step 508 and can include, for example, a threshold number of iterations performed, whether the score goes above a threshold value, or whether the score reaches a peak value. The updating of the pixel location of the protrusion structure, as well as the updating of the best-known position of the protrusion structure, can correspond to step 510 in which the candidate pixelated pattern is adjusted.

Besides PSO algorithms, other optimization algorithms can be used to adjust the candidate pixelated pattern, such as gradient descent, newton methods, or quasi-newton methods. In all these cases, a search for a candidate pixelated pattern that generates a local maxima of the score from the objective function can be performed and the candidate pixelated pattern can be adjusted to increase the score in step 510 until the local maxima is reached. It can be determined that a local maxima is reached when the rate of change of the score with respect to the candidate pixelated pattern is close to zero.

FIG. 5D illustrates a chart 530 that shows the change in the projected attributes of a micro-mirror in different iterations of iterative process 500. Graphs 532a, 532b, 532c, 532d, and 532e describe the changes of, respectively, power efficiency values Peff₅, Peff₁₀, and Peff₁₅, the average power efficiency, and dynamic deformation, in different iterations. As shown in chart 530, in the first iteration, dynamic deformation is at the maximum, whereas the power efficiency values are at their minimum. Before iteration number 100, as the number of iterations increases, the dynamic deformation decreases rapidly, whereas the power efficiency values increase rapidly. After iteration number 100, the dynamic deformation settles at low value, whereas the power efficiency values approach a plateau. When the iteration number reaches 300, process 500 can stop.

Referring back to FIG. 5B, when the predetermined condition in step 510 is satisfied, a mask pattern for fabricating the micro-mirror is generated based on the candidate pixelated pattern. The mask pattern can define whether the back side is etched away to reduce thickness or is to be protected from etching to form a protrusion structure. FIG. 5E illustrates an example of a finalized pixelated pattern 540 and its corresponding mask pattern 550. As shown in FIG. 5E, mask pattern 550 can be formed by expanding pixels of the pixelated pattern 540. The expansion of the pixels can create additional mask area 552 to join two pixels, such as pixels 542 and 544 which are just joined at a corner, to compensate for etching undercut which could otherwise completely separate the two pixels.

### Example Techniques to Fabricate a Micro-Mirror Assembly

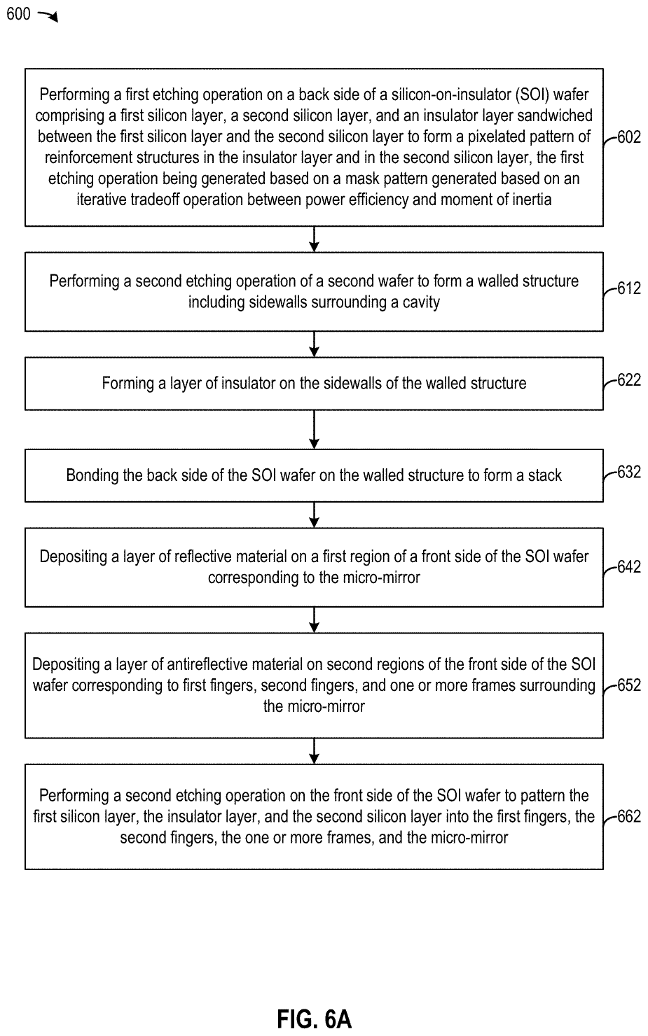

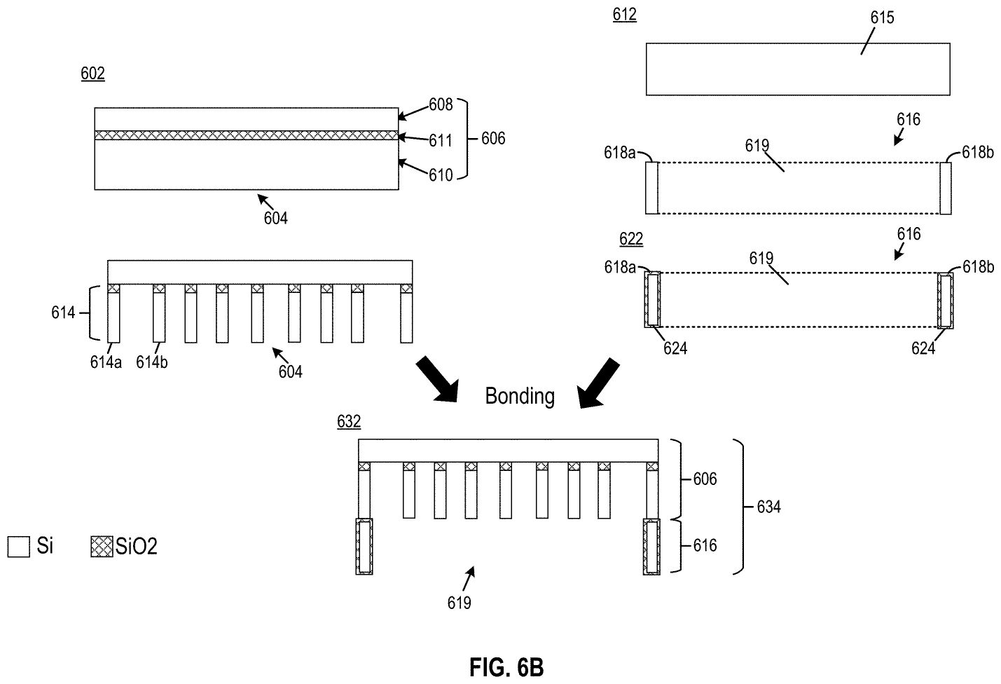

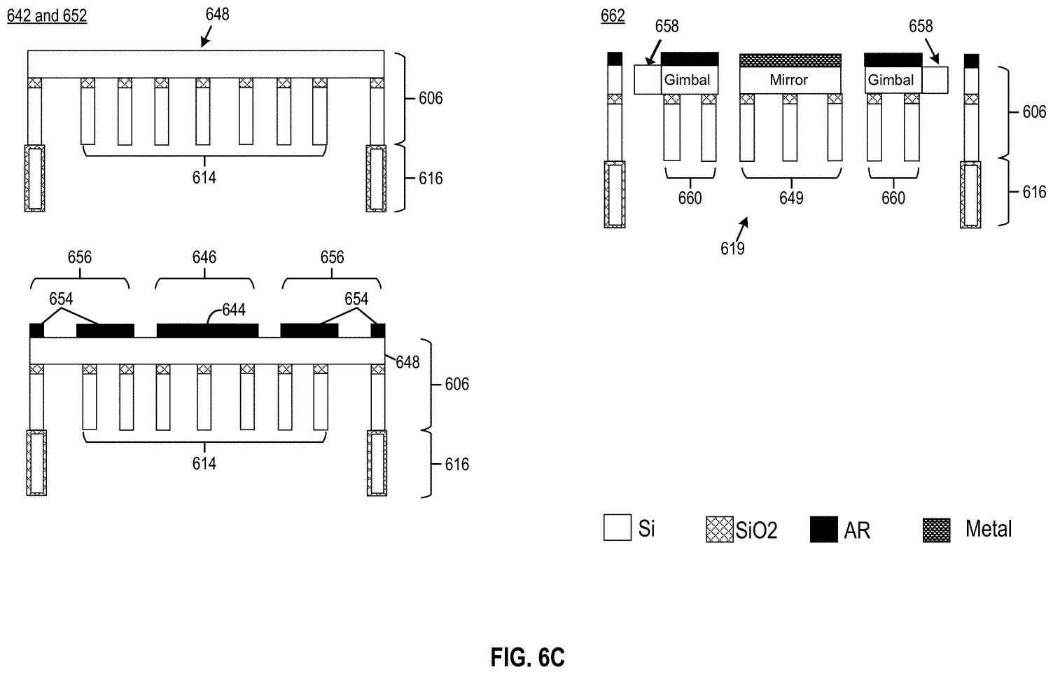

FIG. 6A, FIG. 6B, and FIG. 6C illustrate an example method 800 of fabricating a micro-mirror assembly, such as micro-mirror assembly 252 having a micro-mirror of FIG. 4A. FIG. 6A illustrates a flowchart of method 600, whereas FIG. 6B and FIG. 6C illustrate a cross-section of devices involved in each step of method 600 the fabrication operation.

Referring to FIG. 6A and FIG. 6B, method 600 starts with step 602, in which a first etching operation is performed on a back side 604 of an SOI wafer 606. Referring to FIG. 6B, SOI wafer 606 comprises a first silicon layer 608, a second silicon layer 610, and an insulator layer 611 (e.g., silicon dioxide (SiO₂)) sandwiched between first silicon layer 608 and second silicon layer 610. The first etching operation can be performed on the back side 604 of SOI wafer 606 to form a pixelated pattern of reinforcement structures in insulator layer 611 and in second silicon layer 610. The pixelated pattern of reinforcement structure can include, for example, protrusions structures 614 (e.g., protrusions 614a, 614b). The etching can be based on a pixelated pattern generated based on iterative process 500 of FIG. 5A that trades off between power efficiency/deformation and moment of inertia, as well as expansion of pixels of the pixelated pattern to form a mask pattern as described in FIG. 5E.

In step 612, a second etching operation is performed on a second wafer 615. Referring to FIG. 6B, second wafer 615 can include a single silicon layer. A through-wafer etching operation can be performed to etch through second wafer 615 to form a walled structure 616 including sidewalls 618 (e.g., sidewalls 618a, 618b) and cavity 619. In step 622, a layer of insulator 624 (e.g., SiO₂) can be formed on sidewalls 618 of walled structure 616. The formation of insulator 624 can be based on, for example, thermal oxidation to merge the insulator layer on sidewalls 618 to the reinforcement structure of SOI wafer 606.

In step 632, the back side of SOI wafer 606 can be bonded to walled structure 616 to form a stack 634. As to be described below, a rotatable micro-mirror is to be formed from SOI wafer 606, and cavity 619 below SOI wafer 606 provides space for the micro-mirror to rotate. The bonding can be performed based on, for example, thermal bonding.

Referring to FIG. 6C, in step 642, a layer of reflective material 644 (e.g., a metallic material) can be deposited on a first region 646 of a front side 648 of SOI wafer 606. First region 646 can correspond to a micro-mirror 649 (e.g., micro-mirror 400). Moreover, in step 652, a layer of antireflective material 654 (e.g., silicon nitride) can be deposited on second regions 656 of front side 648 of SOI wafer 606. The second regions can correspond to first fingers and second fingers 658 and to one or more frames 660 that surround the micro-mirror (e.g., gimbal/frame 254).

Referring back to FIG. 6A, in step 662, a second etching operation can be performed on front side 648 of SOI wafer 606 to pattern the first silicon layer, the insulator layer, and the second silicon layer into first and second fingers 658, one or more frames 660, and micro-mirror 649. Cavity 619 below micro-mirror 649, enclosed by sidewalls 618, can provide a free space for the rotation of micro-mirror 649.

### Computing System

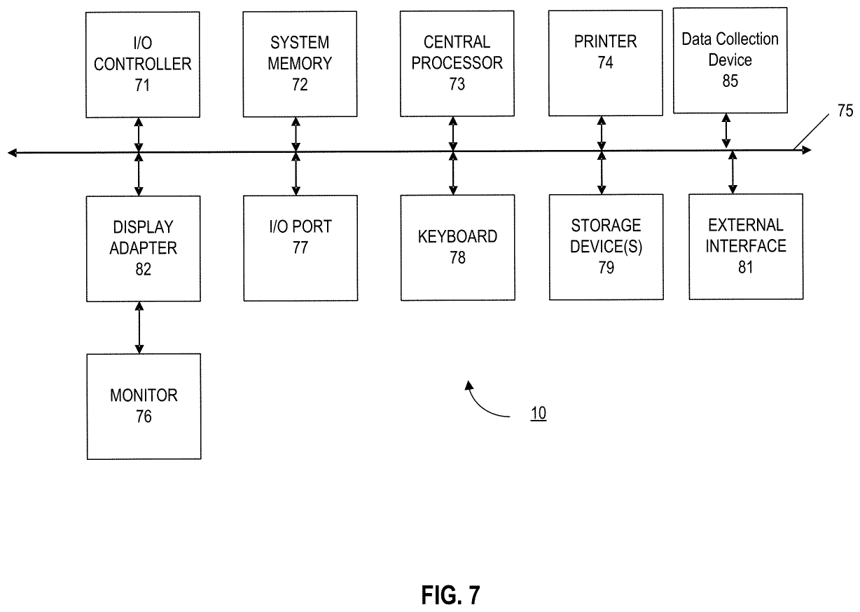

Any of the computing systems mentioned herein may utilize any suitable number of subsystems. Examples of such subsystems are shown in FIG. 7 in computing system 10. In some embodiments, a computing system includes a single computing apparatus, where the subsystems can be the components of the computing apparatus. In other embodiments, a computing system can include multiple computing apparatuses, each being a subsystem, with internal components. Computing system 10 can include, for example, a field programmable gate array (FPGA), an application specific integrated circuit (ASIC), and a general purpose central processing unit (CPU), to implement the disclosed techniques, including the techniques described in FIG. 5A-FIG. 5E. In some examples, computing system 10 can also include desktop and laptop computers, tablets, mobile phones, and other mobile devices.

The subsystems shown in FIG. 7 are interconnected via a system bus 75. Additional subsystems such as a printer 74, keyboard 78, storage device(s) 79, monitor 76, which is coupled to display adapter 82, and others are shown. Peripherals and input/output (I/O) devices, which couple to I/O controller 71, can be connected to the computing system by any number of means known in the art, such as input/output (I/O) port 77 (e.g., USB, FireWire) For example, I/O port 77 or external interface 81 (e.g. Ethernet or Wi-Fi) can be used to connect computing system 10 to a wide area network such as the Internet, a mouse input device, or a scanner. The interconnection via system bus 75 allows the central processor 73, which can be an FPGA, an ASIC, a CPU, etc., to communicate with each subsystem and to control the execution of a plurality of instructions from system memory 72 or the storage device(s) 79 (e.g., a fixed disk, such as a hard drive or optical disk), as well as the exchange of information between subsystems. The system memory 72 and/or the storage device(s) 79 may embody a computer-readable medium. Another subsystem is a data collection device 85, such as a camera, microphone, accelerometer, and the like. Any of the data mentioned herein can be output from one component to another component and can be output to the user.

A computing system can include a plurality of the same components or subsystems, e.g., connected together by external interface 81 or by an internal interface. In some embodiments, computing systems, subsystems, or apparatuses can communicate over a network. In such instances, one computer can be considered a client and another computer a server, where each can be part of a same computing system. A client and a server can each include multiple systems, subsystems, or components.

Aspects of embodiments can be implemented in the form of control logic-using hardware (e.g., an application specific integrated circuit or field programmable gate array) and/or using computer software with a generally programmable processor in a modular or integrated manner. As used herein, a processor includes a single-core processor, multi-core processor on a same integrated chip, or multiple processing units on a single circuit board or networked. Based on the disclosure and teachings provided herein, a person of ordinary skill in the art will know and appreciate other ways and/or methods to implement embodiments of the present invention using hardware and a combination of hardware and software.

Any of the software components or functions described in this application may be implemented as software code to be executed by a processor using any suitable computer language, such as, for example, Java, C, C++, C#, Objective-C, Swift, or scripting language such as Perl or Python using, for example, conventional or object-oriented techniques. The software code may be stored as a series of instructions or commands on a computer-readable medium for storage and/or transmission. A suitable non-transitory computer-readable medium can include random access memory (RAM), a read-only memory (ROM), a magnetic medium such as a hard-drive or a floppy disk, or an optical medium such as a compact disk (CD) or DVD (digital versatile disk), flash memory, and the like. The computer-readable medium may be any combination of such storage or transmission devices.

Such programs may also be encoded and transmitted using carrier signals adapted for transmission via wired, optical, and/or wireless networks conforming to a variety of protocols, including the Internet. As such, a computer-readable medium may be created using a data signal encoded with such programs. Computer-readable media encoded with the program code may be packaged with a compatible device or provided separately from other devices (e.g., via Internet download). Any such computer-readable medium may reside on or within a single computer product (e.g. a hard drive, a CD, or an entire computing system), and may be present on or within different computer products within a system or network. A computing system may include a monitor, printer, or other suitable display for providing any of the results mentioned herein to a user.

Any of the methods described herein may be totally or partially performed with a computer system including one or more processors, which can be configured to perform the steps. Thus, embodiments can be directed to computer systems configured to perform the steps of any of the methods described herein, potentially with different components performing a respective steps or a respective group of steps. Although presented as numbered steps, steps of methods herein can be performed at a same time or in a different order. Additionally, portions of these steps may be used with portions of other steps from other methods. Also, all or portions of a step may be optional. Additionally, any of the steps of any of the methods can be performed with modules, units, circuits, or other means for performing these steps.

Other variations are within the spirit of the present disclosure. Thus, while the disclosed techniques are susceptible to various modifications and alternative constructions, certain illustrated examples thereof are shown in the drawings and have been described above in detail. It should be understood, however, that there is no intention to limit the disclosure to the specific form or forms disclosed, but on the contrary, the intention is to cover all modifications, alternative constructions, and equivalents falling within the spirit and scope of the disclosure, as defined in the appended claims. For instance, any of the examples, alternative examples, etc., and the concepts thereof may be applied to any other examples described and/or within the spirit and scope of the disclosure.

The use of the terms “a,” “an,” and “the” and similar referents in the context of describing the disclosed examples (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning including, but not limited to) unless otherwise noted. The term “connected” is to be construed as partly or wholly contained within, attached to, or joined together, even if there is something intervening. The phrase “based on” should be understood to be open-ended and not limiting in any way and is intended to be interpreted or otherwise read as “based at least in part on,” where appropriate. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order, unless otherwise indicated herein or otherwise clearly contradicted by context. The use of any and all examples or exemplary language (e.g., “such as”) provided herein, is intended merely to better illuminate examples of the disclosure and does not pose a limitation on the scope of the disclosure, unless otherwise claimed. No language in the specification should be construed as indicating any non-claimed element as essential to the practice of the disclosure.

What is claimed is:

1. An apparatus, the apparatus being part of a Light Detection and Ranging (LiDAR) module of a vehicle and comprising:
a semiconductor integrated circuit comprising a microelectromechanical system (MEMS) and a substrate, the MEMS comprising an array of micro-mirror assemblies, each micro-mirror assembly comprising:
a micro-mirror having a pixelated pattern of reinforcement structures on a back-side surface, the pixelated pattern being defined based on dividing the back-side surface into an array of pixels and comprising protrusion structures that protrude from the back-side surface, the pixelated pattern of reinforcement structures comprising non-uniform sub-patterns having non-uniform geometric planar shapes, non-uniform planar sizes, and non-uniform planar orientations on the back-side surface; and
an actuator to rotate the micro-mirror to reflect light emitted by a light source out of the LiDAR module or to reflect light received by the LiDAR module to a receiver.

2. The apparatus of claim 1, wherein the pixelated pattern of reinforcement structures comprises a first reinforcement structure and a second reinforcement structure, the first reinforcement structure forming a pixelated slanted line with respect to the second reinforcement structure.

3. The apparatus of claim 1, wherein the pixelated pattern of reinforcement structures comprises a first reinforcement structure and a second reinforcement structure, the first reinforcement structure and the second reinforcement structure having no connecting reinforcement structure in between.

4. The apparatus of claim 1, wherein the pixelated pattern of reinforcement structures comprises at least one of:
a first reinforcement structure having a non-uniform width that spans a non-uniform number of pixels; or
second reinforcement structures that are parallel with each other and having different lengths that span different numbers of pixels.

5. The apparatus of claim 1, wherein the pixelated pattern of reinforcement structures comprises a plurality of identical pixelated sub-patterns.

6. The apparatus of claim 1, wherein the pixelated pattern of reinforcement structures is determined based on reducing or minimizing a degree of deformation of the micro-mirror across a range of rotation angles of the micro-mirror.

7. The apparatus of claim 1, wherein the pixelated pattern of reinforcement structures is determined based on increasing or maximizing a power efficiency of the micro-mirror across a range of rotation angles of the micro-mirror; and
wherein the power efficiency defines a ratio of power between first light received in a predetermined window in a far field from the micro-mirror with deformation and second light received in the predetermined window in the far field from the micro-mirror without deformation.

8. The apparatus of claim 1, wherein the pixelated pattern of reinforcement structures is determined based on an optimization operation that trades off between a power efficiency of the micro-mirror and an attribute of the pixelated pattern; and
wherein the power efficiency defines a ratio of power between first light received in a predetermined window in a far field from the micro-mirror with deformation and second light received in the predetermined window in the far field from the micro-mirror without deformation.

9. The apparatus of claim 8, wherein the attribute includes a total number of pixels of the pixelated pattern having a reinforcement structure.

10. The apparatus of claim 8, wherein the attribute includes a moment of inertia of micro-mirror having the pixelated pattern of reinforcement structures.

11. The apparatus of claim 8, wherein the optimization operation includes at least one of: a particle swarm optimization (PSO) operation, a gradient descent operation, a quasi-newton method, or a newton method.

12. The apparatus of claim 8, wherein the optimization operation generates a raw pixelated pattern;
wherein the pixelated pattern of reinforcement structures is fabricated based on a mask pattern; and
wherein the mask pattern is generated by expanding pixels of the raw pixelated pattern to compensate for etching undercut.

13. The apparatus of claim 1, further comprising a gimbal structure surrounding and coupled with the micro-mirror; and
wherein the actuator is coupled with the gimbal structure and is configured to rotate the micro-mirror based on rotating the gimbal structure.

14. The apparatus of claim 1, further comprising a controller;
wherein the light source is a pulsed light source; and
wherein the controller is configured to:
control the light source to generate a first light pulse at a first time;
control the actuator to set a first angle of an output projection path to project the first light pulse towards an object along the output projection path;
control the actuator to set a second angle of an input path to steer a second light pulse reflected from the object to the receiver, the second light pulse being received at the receiver at a second time; and
determine a location of the object with respect to the apparatus based on a difference between the first time and the second time, the first angle, and the second angle.

15. A computer-implemented method of generating a mask pattern for fabricating a micro-mirror, the method comprising:
obtaining a candidate pixelated pattern of reinforcement structures to be formed on a back side of the micro-mirror;
determining one or more first attributes of the micro-mirror having the candidate pixelated pattern, the one or more first attributes comprising at least one of: a total moment of inertia of the micro-mirror or a total number of pixels of the pixelated pattern having a protrusion structure;
determining one or more second attributes of the micro-mirror having the candidate pixelated pattern, the one or more second attributes comprising at least one of: a degree of deformation of the micro-mirror across a range of rotation angles or a power efficiency of the micro-mirror that defines a ratio of power between first light received in a predetermined window in a far field from the micro-mirror with deformation and second light received in the predetermined window in the far field from the micro-mirror without deformation;
adjusting the candidate pixelated pattern based on the one or more first attributes and the one or more second attributes; and
based on a predetermined condition being satisfied, generating the mask pattern based on the candidate pixelated pattern.

16. The method of claim 15, further comprising:
applying an objective function to the one or more first attributes to obtain a score, wherein the score is negatively influenced by the one or more first attributes and positively influenced by the one or more second attributes; and
adjusting the candidate pixelated pattern based on the score; and
wherein the predetermined condition comprises at least one of: the score exceeding a threshold or the score reaching a maximum.

17. The method of claim 15, wherein the predetermined condition comprises a number of iterations by which the candidate pixelated pattern is adjusted and exceeds a threshold.

18. The method of claim 15, wherein the predetermined condition and the adjustment of the candidate pixelated pattern are defined based on an optimization algorithm comprising at least one of: a PSO operation, a gradient descent operation, a quasi-newton method, or a newton method.

19. A method of manufacturing a micro-mirror assembly, comprising:
performing a first etching operation on a back side of a silicon-on-insulator (SOI) wafer comprising a first silicon layer, a second silicon layer, and an insulator layer sandwiched between the first silicon layer and the second silicon layer to form a plurality of reinforcement structures in the insulator layer and in the second silicon layer, the first etching operation being generated based on a mask pattern generated based on an iterative tradeoff operation between power efficiency and moment of inertia;
performing a second etching operation of a second wafer to form a walled structure including sidewalls surrounding a cavity;
bonding the back side of the SOI wafer on the walled structure to form a stack; and
performing a third etching operation on a front side of the SOI wafer to pattern the first silicon layer, the insulator layer, and the second silicon layer into first fingers, second fingers, and a micro-mirror, such that the second fingers are mechanically connected to the micro-mirror and the first fingers and the second fingers are separated by a gap; and
wherein the micro-mirror is rotatable in the cavity based on an electrostatic force between the first fingers and the second fingers.

20. The method of claim 19, wherein the iterative tradeoff operation comprises at least one of: a PSO operation, a gradient descent operation, a quasi-newton method, or a newton method.
